(19) United States
(12) Patent Application Publication
(10) Pub. No.: US 2026/0101792 A1
(43) Pub. Date: Apr. 9, 2026

(54) METHOD FOR MANUFACTURING SEMICONDUCTOR STACK STRUCTURE WITH ULTRA THIN DIES

(71) Applicant: Nexthin Technology, George Town Grand Cayman (KY)

(72) Inventors: TZU-WEI CHIU, George Town Grand Cayman (KY); JEN-HAO YEH, George Town Grand Cayman (KY)

(21) Appl. No.: 19/001,513

(22) Filed: Dec. 25, 2024

(30) Foreign Application Priority Data
Oct. 4, 2024 (TW) 113137912

(51) Int. Cl. H01L 23/00

(52) U.S. Cl. CPC H10W 72/0198; H10W 72/01951; H10W 72/01953; H10W 72/01961; H10W 80/211; H10W 80/312; H10W 80/327; H10W 90/792

(57) ABSTRACT

A method for manufacturing a semiconductor stack structure with ultra thin dies includes manufacturing a plurality of semiconductor wafers. A carrier board is bonded to the redistribution layer of one of the semiconductor wafers, then the second substrate part and the stop layer structure are removed to expose the first substrate part, and the wafer conductive structures are penetrated thereon and connected to the redistribution layer. By thinning the first substrate part, the wafer conductive structures are protruded, and a bonding dielectric layer is formed to cover the wafer conductive structures and is thinned to expose the wafer conductive structure. A bonding layer with conductive pillars is formed on the redistribution layer of another semiconductor wafer, and a die sawing is performed to form a plurality of batches of dies. The bonding layers of a batch of dies are bonded to the bonding dielectric layer by using hybrid bonding technology.

### FIELD OF THE INVENTION

The present invention relates to a method for manufacturing a semiconductor structure, particularly a method for manufacturing a semiconductor stack structure with ultra thin dies.

### BACKGROUND OF THE INVENTION

With the rapid development of the electronics industry, electronic products are gradually moving towards multifunctional and high-performance research and development directions. Semiconductor technologies have been widely applied to manufacture chipsets such as memories and central processing units. To achieve objectives such as high integration (Integration) and high speed, the size of semiconductor integrated circuits continues to reduce. Currently, various materials and technologies have been developed to meet the requirements of integration and speed, for example, the development of a stack structure including multiple substrates (multiple substrates), to increase the circuit operating speed. When the planar packaging technology of semiconductors reaches its limit, integration can meet the demands for miniaturization. The technology of stacking wafers will greatly contribute to future technology and has become a target to be improved urgently in related fields.

### SUMMARY OF THE INVENTION

The present invention provides a method for manufacturing a semiconductor stack structure with ultra thin dies, which can improve the stability of the semiconductor stack structure with ultra thin dies.

To achieve one, some, or all of the above objectives or other objectives, an embodiment of the present invention provides a method for manufacturing a semiconductor stack structure with ultra thin dies, including: manufacturing a plurality of semiconductor wafers, where manufacturing steps for each of the semiconductor wafers include: providing a semiconductor substrate having an active surface and a back surface opposite each other; forming a stop layer structure in the semiconductor substrate to divide the semiconductor substrate into a first substrate part and a second substrate part, where the first substrate part is located between the stop layer structure and the active surface, the second substrate part is located between the stop layer structure and the back surface, the stop layer structure includes a dielectric stop layer, and the dielectric stop layer is manufactured by performing an ion implantation process at a depth of the semiconductor substrate and performing a high-temperature treatment process, such that the dielectric stop layer is formed in a region for the ion implantation process; and sequentially forming an epitaxial layer, an active layer, a redistribution layer, and a first bonding layer on the active surface; providing a carrier board and forming a second bonding layer on the carrier board; selecting one of the semiconductor wafers as a first semiconductor wafer, and inverting the first semiconductor wafer to bond the first bonding layer of the first semiconductor wafer with the second bonding layer; removing the second substrate part of the first semiconductor wafer and the stop layer structure to expose the first substrate part of the first semiconductor wafer; forming a plurality of wafer conductive structures that penetrate the first substrate part, the epitaxial layer, and the active layer of the first semiconductor wafer to be connected to the redistribution layer, and thinning the first substrate part, such that the wafer conductive structures protrude out of the first substrate part; forming a first bonding dielectric layer on the first substrate part of the first semiconductor wafer to cover the wafer conductive structures, and thinning the first bonding dielectric layer to expose the wafer conductive structures; selecting another one of the semiconductor wafers as a second semiconductor wafer, disposing a plurality of conductive pillars on the first bonding layer of the second semiconductor wafer to be electrically connected to the redistribution layer, and performing die sawing on the second semiconductor wafer to form a first batch of semiconductor dies and a second batch of semiconductor dies that are to be stacked; inverting the first batch of semiconductor dies, such that the first bonding layer of the first batch of semiconductor dies and the first bonding dielectric layer are opposite each other and bonded together through a hybrid bonding technology, where the conductive pillars of the first batch of semiconductor dies respectively correspond to and are electrically connected to the wafer conductive structures; performing a back surface grinding process on the second substrate part of the first batch of semiconductor dies to thin the second substrate part; forming on the first bonding dielectric layer a first packaging colloid that covers the first batch of semiconductor dies and fills up gaps between the first batch of semiconductor dies; removing part of the first packaging colloid and removing the second substrate part and the stop layer structure of the first batch of semiconductor dies to expose the first substrate part of the first batch of semiconductor dies; forming a plurality of first die conductive structures that penetrate the first substrate part, the epitaxial layer, and the active layer of the first batch of semiconductor dies to be connected to the redistribution layer, and thinning the first substrate part and the first packaging colloid, such that the first die conductive structures protrude out of the first substrate part of the first batch of semiconductor dies; and forming a second bonding dielectric layer on the first substrate part and the first packaging colloid of the first batch of semiconductor dies to cover the first die conductive structures, and thinning the second bonding dielectric layer to expose the first die conductive structures.

In an embodiment of the present invention, after the first die conductive structures are exposed, the method further includes: inverting the second batch of semiconductor dies, such that the first bonding layer of the second batch of semiconductor dies and the second bonding dielectric layer are opposite each other and bonded together through the hybrid bonding technology, where the conductive pillars of the second batch of semiconductor dies respectively correspond to and are electrically connected to the first die conductive structures; forming on the second bonding dielectric layer a second packaging colloid that covers the second batch of semiconductor dies and fills up gaps between the second batch of semiconductor dies; removing part of the second packaging colloid and removing the second substrate part and the stop layer structure of the second batch of semiconductor dies to expose the first substrate part of the second batch of semiconductor dies; forming a plurality of second die conductive structures that penetrate the first substrate part, the epitaxial layer, and the active layer of the second batch of semiconductor dies to be connected to the redistribution layer, and thinning the first substrate part and the second packaging colloid, such that the second die conductive structures protrude out of the first substrate part of the second batch of semiconductor dies; and forming a third bonding dielectric layer on the first substrate part and the second packaging colloid of the second batch of semiconductor dies to cover the second die conductive structures, and thinning the third bonding dielectric layer to expose the second die conductive structures.

In an embodiment of the present invention, the method further includes: providing a dummy carrier board, forming a third bonding layer on the dummy carrier board, and bonding the third bonding layer with the third bonding dielectric layer; removing the carrier board to expose the second bonding layer; forming a plurality of grooves in the second bonding layer and the first bonding layer of the first semiconductor wafer to expose the redistribution layer of the first semiconductor wafer; respectively disposing a plurality of solder balls in the grooves, and electrically connecting the solder balls to the redistribution layer; and performing die sawing at a position of the second batch of semiconductor dies.

In an embodiment of the present invention, the method for forming the stop layer structure includes: performing a first ion implantation process at a first depth of the semiconductor substrate; performing a second ion implantation process at a second depth of the semiconductor substrate, where the second depth is different from the first depth, and an element used for the first ion implantation process is different from an element used for the second ion implantation process; and performing a high-temperature treatment process, such that a deep dielectric stop layer is formed in a region for the first ion implantation process, and the dielectric stop layer is formed in a region for the second ion implantation process, the dielectric stop layer being located between the deep dielectric stop layer and the active surface.

In an embodiment of the present invention, the element used for the first ion implantation process and the element used for the second ion implantation process are selected from boron, carbon, nitrogen, fluorine, phosphorus, argon, and arsenic.

In an embodiment of the present invention, the step of removing the second substrate part of the first semiconductor wafer and the stop layer structure includes: performing a back surface grinding process to remove part of the second substrate part from a side of the second substrate part away from the stop layer structure; performing a wet etching process to remove the other part of the second substrate part, so as to expose the deep dielectric stop layer, where an etching selectivity ratio of the deep dielectric stop layer to the second substrate part is between 1/10 and 1/300; performing a dry etching process to remove the deep dielectric stop layer, so as to expose the dielectric stop layer, where an etching selectivity ratio of the dielectric stop layer to the deep dielectric stop layer is between ⅕ and 1/100; and performing a dry etching process to remove the dielectric stop layer, so as to expose the first substrate part, where an etching selectivity ratio of the first substrate part to the dielectric stop layer is between ⅕ and 1/100.

In an embodiment of the present invention, after the first packaging colloid is formed to cover the first batch of semiconductor dies, the step of removing part of the first packaging colloid and removing the second substrate part and the stop layer structure of the first batch of semiconductor dies includes: performing a chemical mechanical polishing process to polish part of the first packaging colloid on the second substrate part of the first batch of semiconductor dies; performing a wet etching process to remove the thinned second substrate part of the first batch of semiconductor dies and part of the first packaging colloid, so as to expose the deep dielectric stop layer of the first batch of semiconductor dies, where an etching selectivity ratio of the deep dielectric stop layer to the second substrate part is between 1/10 and 1/300; performing a dry etching process to remove the deep dielectric stop layer of the first batch of semiconductor dies and part of the first packaging colloid, so as to expose the dielectric stop layer of the first batch of semiconductor dies, where an etching selectivity ratio of the dielectric stop layer to the deep dielectric stop layer is between ⅕ and 1/100; and performing a dry etching process to remove the dielectric stop layer of the first batch of semiconductor dies, so as to expose the first substrate part of the first batch of semiconductor dies, where an etching selectivity ratio of the first substrate part to the dielectric stop layer is between ⅕ and 1/100.

In an embodiment of the present invention, the epitaxial layer is deposited on the active surface through a metal-organic chemical vapor deposition process, and at least one active element is further formed on the epitaxial layer.

In an embodiment of the present invention, the step of forming the wafer conductive structures includes: forming a plurality of through holes penetrating the first substrate part, the epitaxial layer, and the active layer of the first semiconductor wafer; sequentially conformally forming an insulating layer and a barrier layer on side walls and bottom walls of the through holes; and disposing a conductive material in the through holes.

In an embodiment of the present invention, the step of forming the first die conductive structures includes: forming a plurality of through holes penetrating the first substrate part and the epitaxial layer of the first batch of semiconductor dies; sequentially conformally forming an insulating layer and a barrier layer on side walls and bottom walls of the through holes; and disposing a conductive material in the through holes.

In an embodiment of the present invention, the first bonding layer and the second bonding layer are bonded together through a melting bonding process.

An embodiment of the present invention provides a method for manufacturing a semiconductor stack structure with ultra thin dies, including: manufacturing a plurality of semiconductor wafers; providing a carrier board and forming a second bonding layer on the carrier board; selecting one of the semiconductor wafers as a first semiconductor wafer, and inverting the first semiconductor wafer to bond a first bonding layer of the first semiconductor wafer with the second bonding layer; removing a second substrate part of the first semiconductor wafer and a stop layer structure to expose a first substrate part of the first semiconductor wafer; forming a plurality of wafer conductive structures that penetrate the first substrate part, an epitaxial layer, and an active layer of the first semiconductor wafer to be connected to a redistribution layer, and thinning the first substrate part, such that the wafer conductive structures protrude out of the first substrate part; forming a first dielectric layer on the first substrate part of the first semiconductor wafer to cover the wafer conductive structures, and thinning the first dielectric layer to expose the wafer conductive structures; forming a first bonding dielectric layer on the first dielectric layer and the wafer conductive structures, where a plurality of first conductive blocks penetrate the first bonding dielectric layer, and the first conductive blocks are electrically connected to the wafer conductive structures, respectively; inverting the first batch of semiconductor dies, such that the first bonding layer of the first batch of semiconductor dies and the first bonding dielectric layer are opposite each other and bonded together through a hybrid bonding technology, where the conductive pillars of the first batch of semiconductor dies respectively correspond to and are electrically connected to the first conductive blocks; performing a back surface grinding process on the second substrate part of the first batch of semiconductor dies to thin the second substrate part; forming on the first bonding dielectric layer a first packaging colloid that covers the first batch of semiconductor dies and fills up gaps between the first batch of semiconductor dies; removing part of the first packaging colloid and removing the second substrate part and the stop layer structure of the first batch of semiconductor dies to expose the first substrate part of the first batch of semiconductor dies; forming a plurality of first die conductive structures that penetrate the first substrate part, the epitaxial layer, and the active layer of the first batch of semiconductor dies to be connected to the redistribution layer, and thinning the first substrate part of the first batch of semiconductor dies, such that the first die conductive structures protrude out of the first substrate part; forming a second dielectric layer on the first packaging colloid and the first substrate part of the first batch of semiconductor dies, and thinning the second dielectric layer to expose the first die conductive structure; and forming a second bonding dielectric layer on the second dielectric layer and the first die conductive structures, where a plurality of second conductive blocks penetrate the second bonding dielectric layer, and the second conductive blocks are electrically connected to the first die conductive structures, respectively.

In an embodiment of the present invention, after the second bonding dielectric layer penetrated by the second conductive blocks is formed, the method further includes: inverting the second batch of semiconductor dies, such that the first bonding layer of the second batch of semiconductor dies and the second bonding dielectric layer are opposite each other and bonded together through the hybrid bonding technology, where the conductive pillars of the second batch of semiconductor dies respectively correspond to and are electrically connected to the second conductive blocks; performing a back surface grinding process on the second substrate part of the second batch of semiconductor dies to thin the second substrate part; forming on the second bonding dielectric layer a second packaging colloid that covers the second batch of semiconductor dies and fills up gaps between the second batch of semiconductor dies; removing part of the second packaging colloid and removing the second substrate part and the stop layer structure of the second batch of semiconductor dies to expose the first substrate part of the second batch of semiconductor dies; forming a plurality of second die conductive structures that penetrate the first substrate part, the epitaxial layer, and the active layer of the second batch of semiconductor dies to be connected to the redistribution layer, and thinning the first substrate part of the second batch of semiconductor dies, such that the second die conductive structures protrude out of the first substrate part; forming a third dielectric layer on the second packaging colloid and the first substrate part of the second batch of semiconductor dies, and thinning the third dielectric layer to expose the second die conductive structure; and forming a third bonding dielectric layer on the third dielectric layer and the second die conductive structures, where a plurality of third conductive blocks penetrate the third bonding dielectric layer, and the third conductive blocks are electrically connected to the second die conductive structures, respectively.

In the present invention, a multi-layer 3D die structure can be formed through continuous face-to-face stacking of semiconductor dies. The stop layer structure in each batch of semiconductor dies can create a robust etching stop mechanism, thereby preventing wafer warpage and total thickness variation (TTV). Because the second substrate part, the deep dielectric stop layer, and the dielectric stop layer have different etching selectivity ratios, the process window (process window) can be increased during the thinning process of each batch of semiconductor dies through continuous wet etching, dry etching, and chemical mechanical polishing (CMP) processes, thereby improving the stability of the semiconductor stack structure with ultra thin dies.

Other objectives, features and advantages of the invention will be further understood from the further technological features disclosed by the embodiments of the invention wherein there are shown and described preferred embodiments of this invention, simply by way of illustration of modes best suited to carry out the invention.

### BRIEF DESCRIPTION OF THE DRAWINGS

FIGS. 1A to 1V are schematic cross-sectional views of a method for manufacturing a semiconductor stack structure with ultra thin dies according to a first embodiment of the present invention;

FIGS. 2A and 2B are schematic flowcharts of manufacturing semiconductor dies according to an embodiment of the present invention;

FIGS. 3A and 3B are schematic cross-sectional views of a method for manufacturing a stop layer structure according to an embodiment of the present invention; and

FIGS. 4A to 4Q are schematic cross-sectional views of some stages of the method for manufacturing a semiconductor stack structure with ultra thin dies according to a second embodiment of the present invention.

### DETAILED DESCRIPTION OF PREFERRED EMBODIMENTS

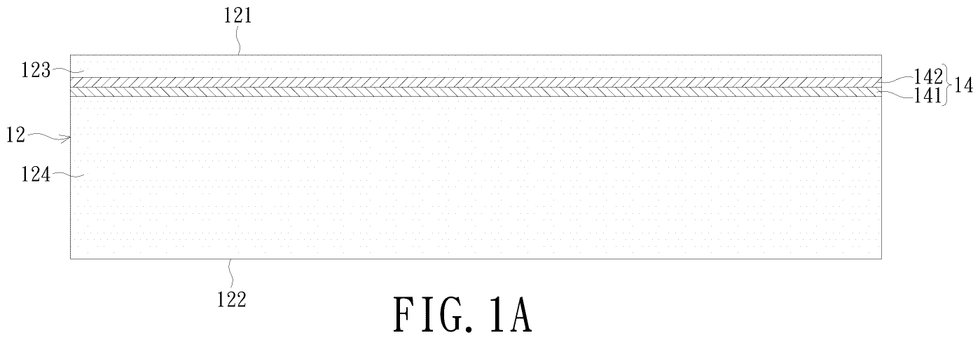

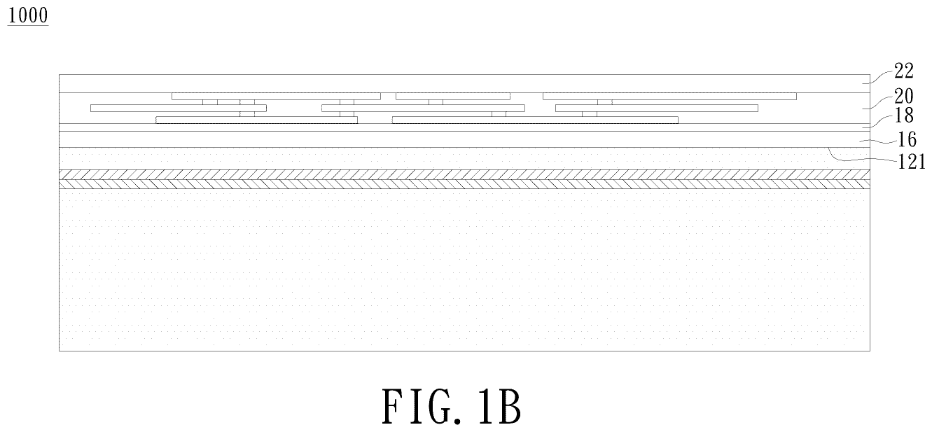

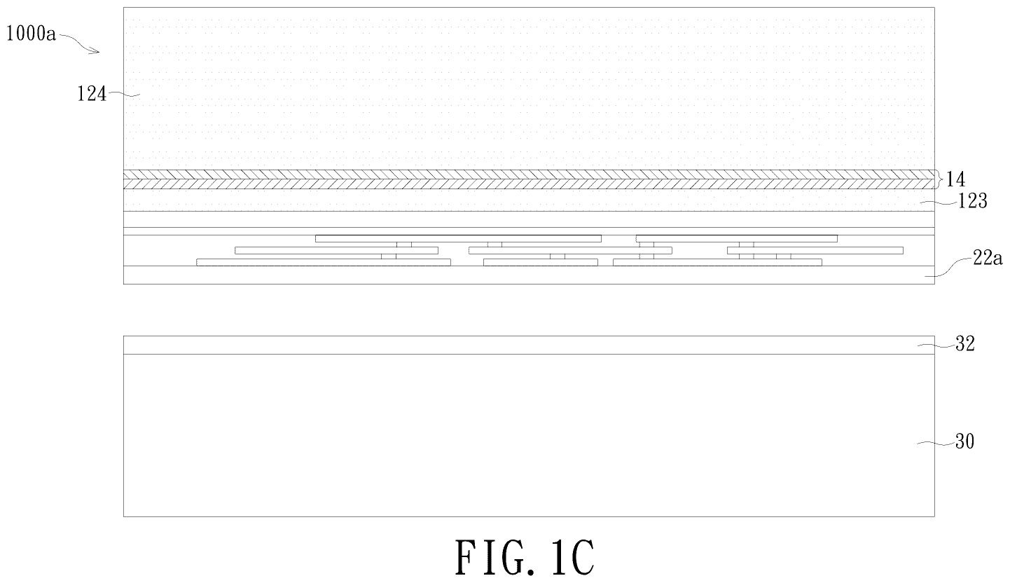

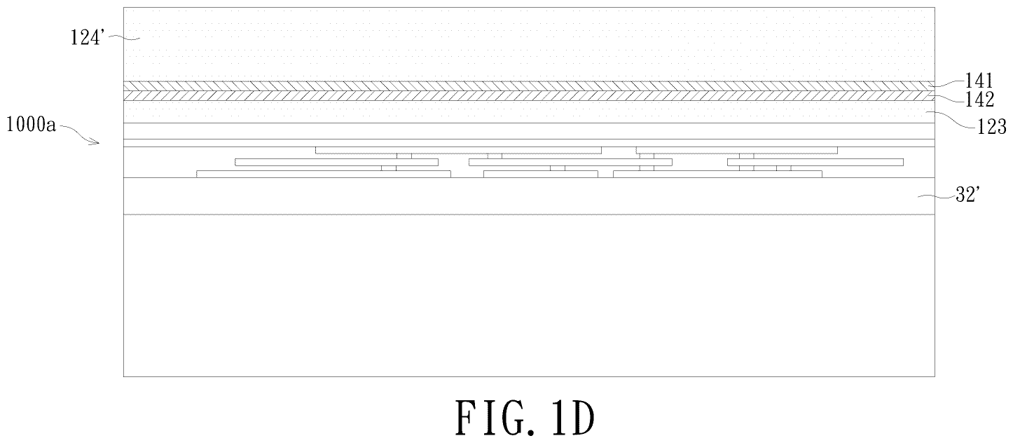

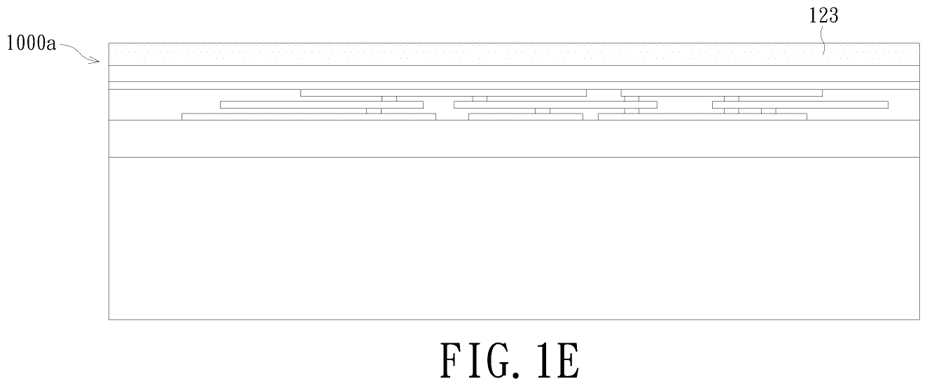

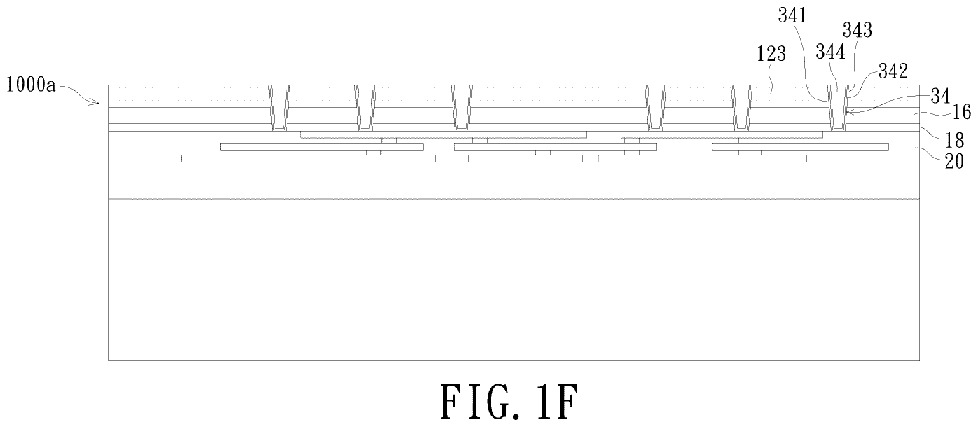

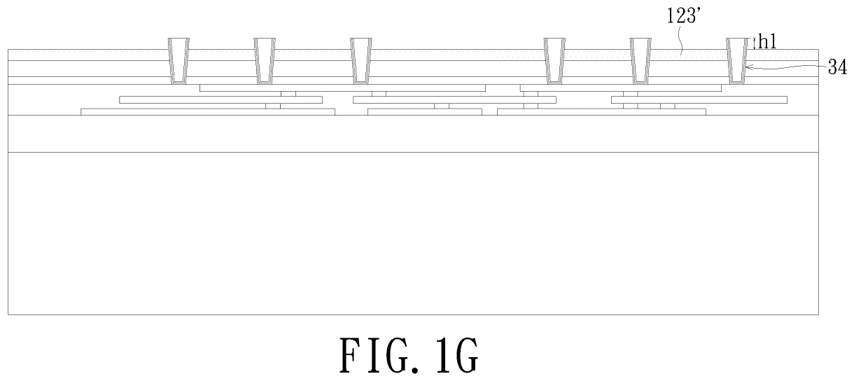

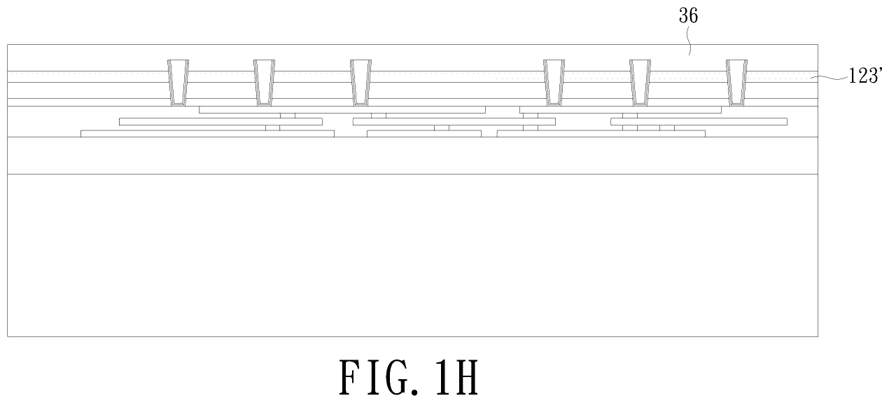

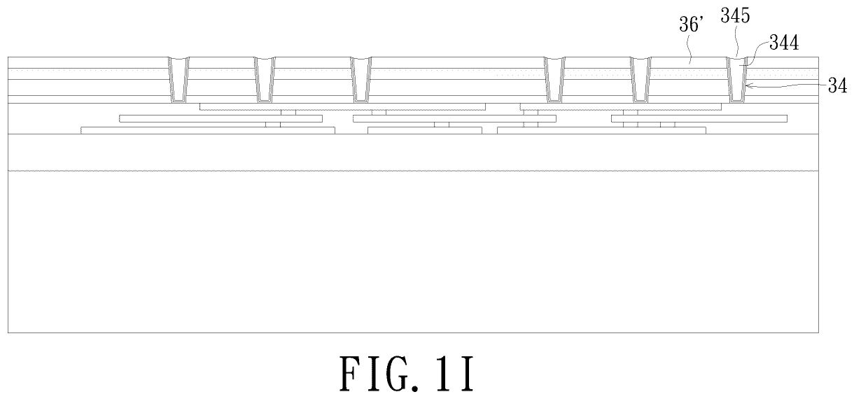

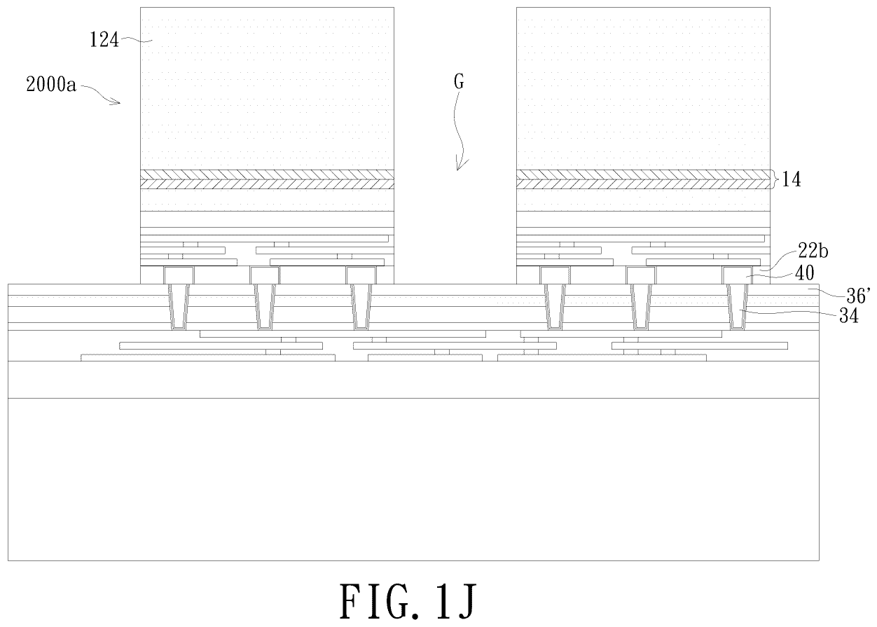

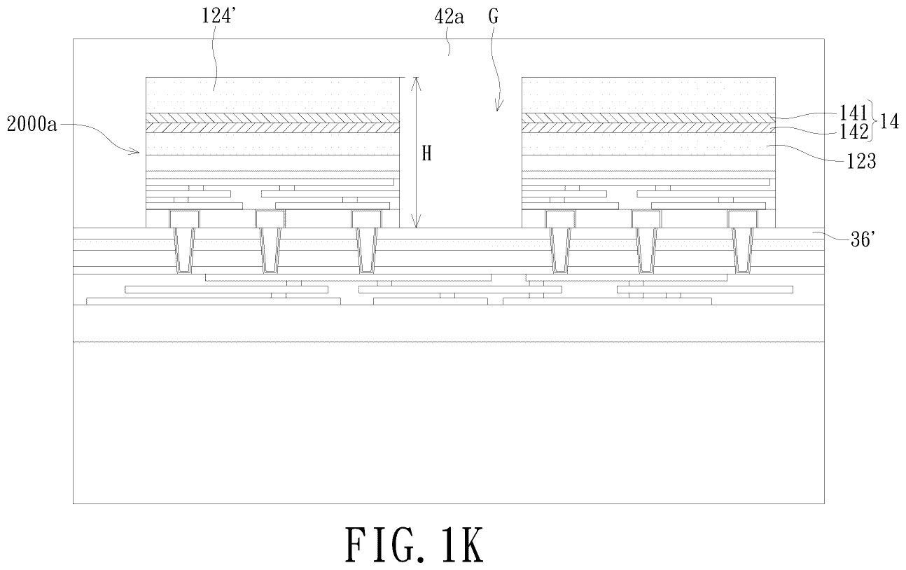

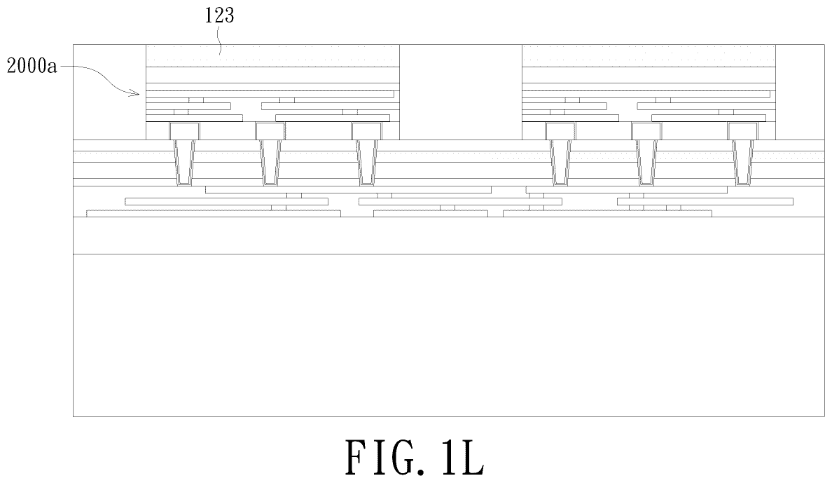

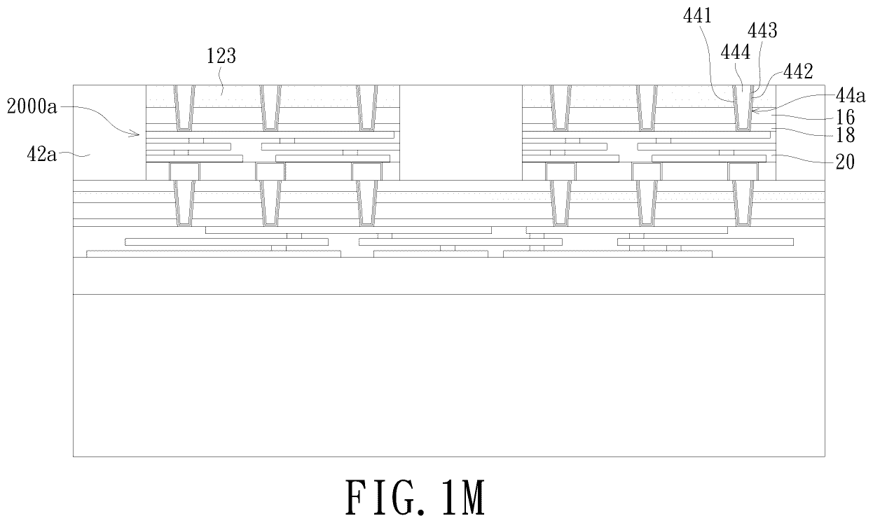

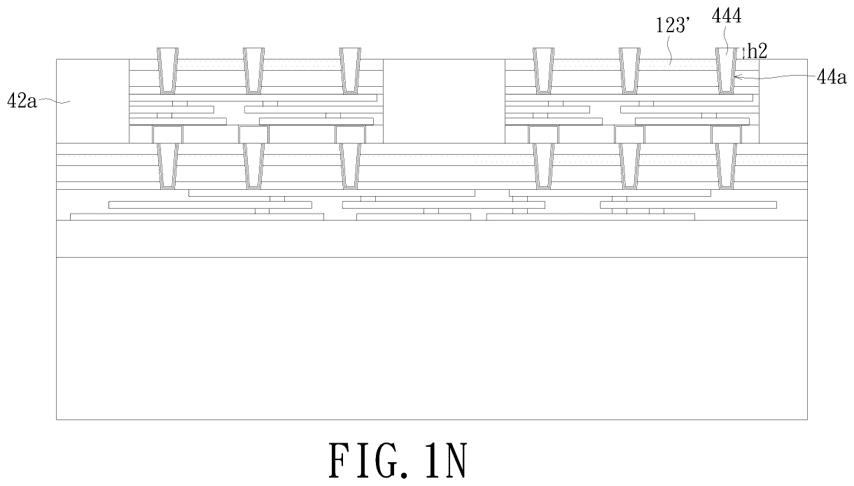

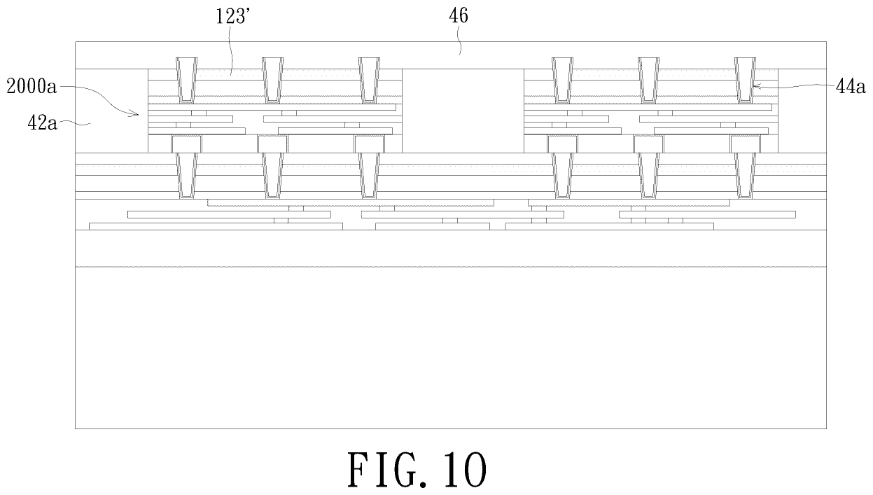

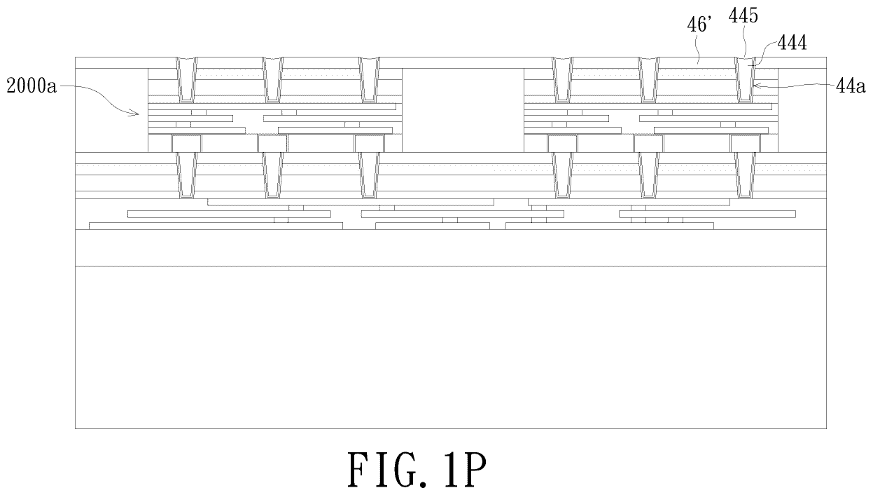

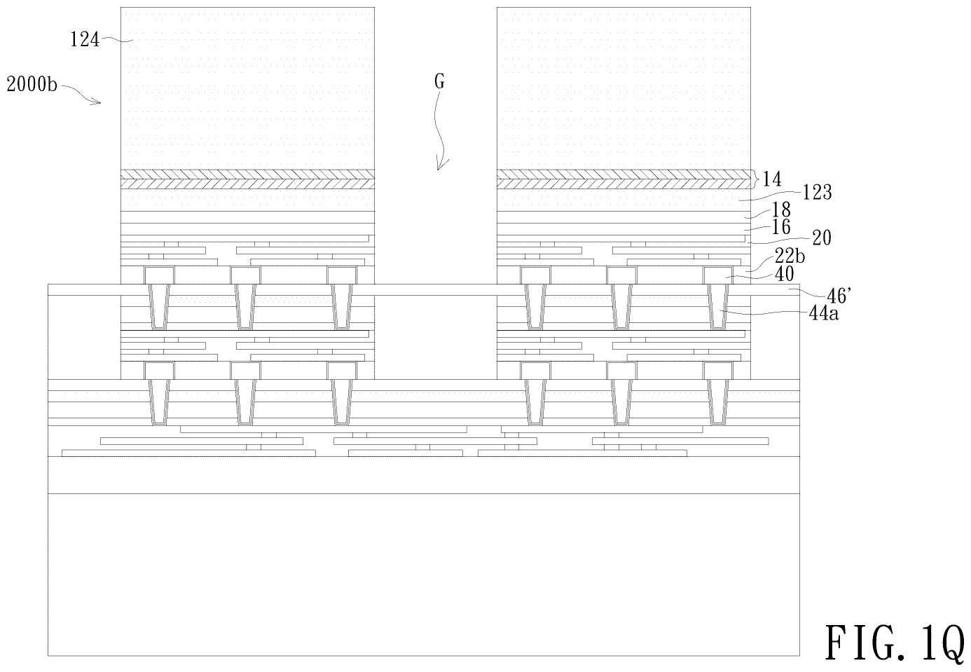

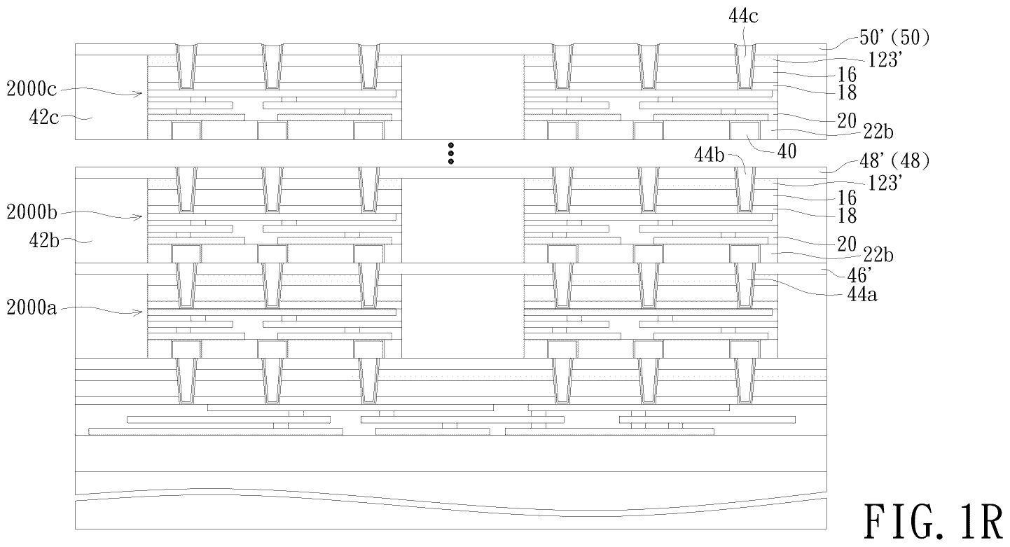

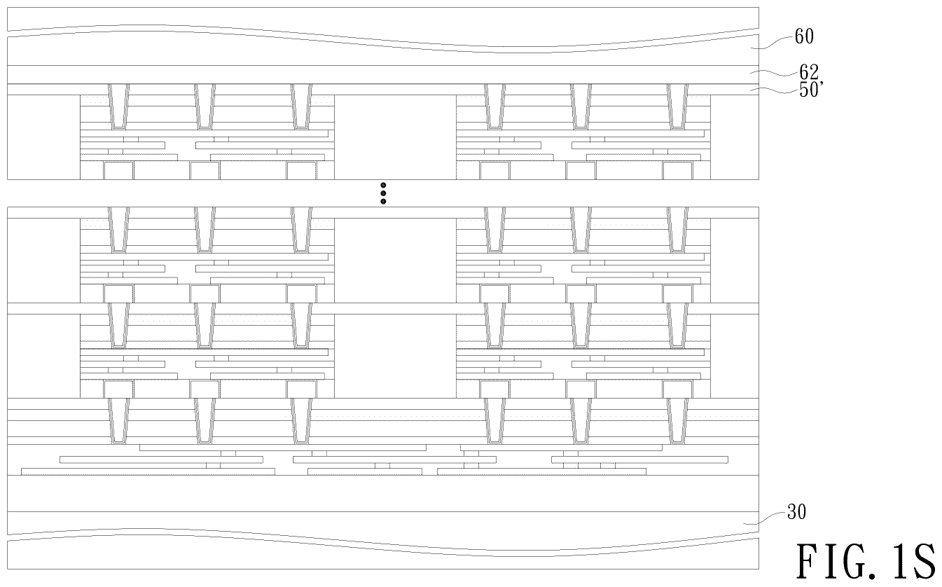

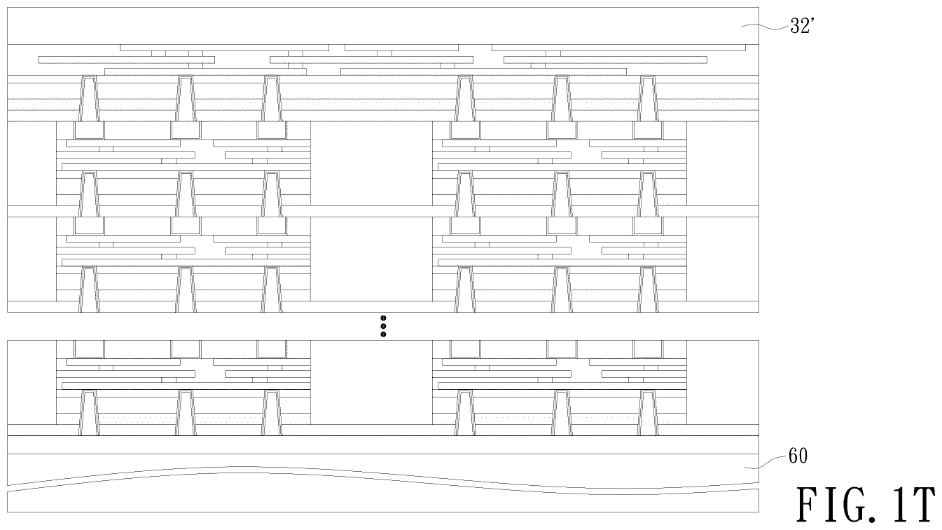

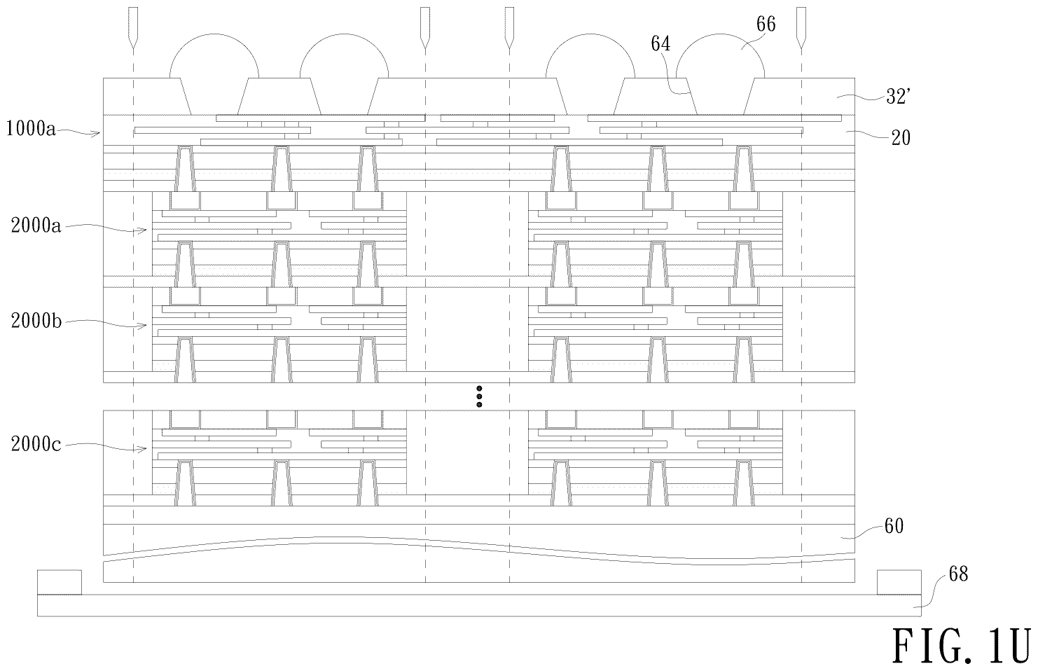

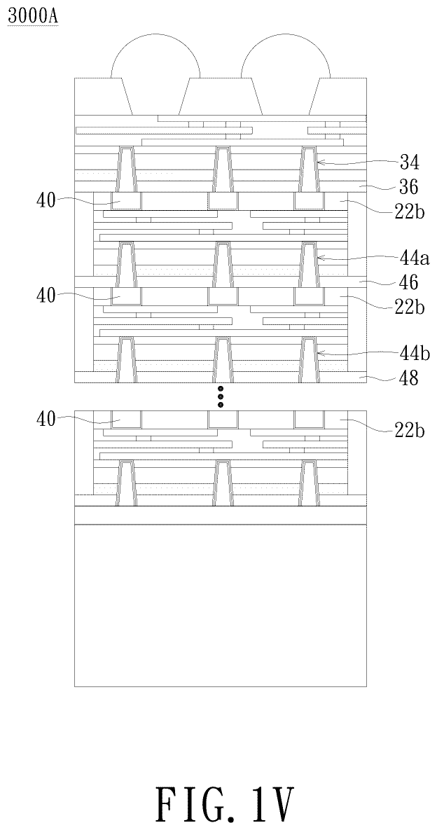

FIGS. 1A to 1V are schematic cross-sectional views of a method for manufacturing a semiconductor stack structure with ultra thin dies according to a first embodiment of the present invention. First, a plurality of semiconductor wafers 1000 (marked in FIG. 1B) are manufactured. FIGS. 1A and 1B are schematic cross-sectional views for manufacturing the semiconductor wafers 1000. As shown in FIG. 1A, a semiconductor substrate 12 is provided. The thickness of the semiconductor substrate 12 is, for example, between 700 and 800 micrometers (μm), preferably 775 micrometers. The semiconductor substrate 12 has an active surface 121 and a back surface 122 opposite each other. A stop layer structure 14 is formed in the semiconductor substrate 12, dividing the semiconductor substrate 12 into a first substrate part 123 and a second substrate part 124. The first substrate part 123 is located between the stop layer structure 14 and the active surface 121, and a thickness of the first substrate part 123 is between 50 nanometers (nm) and 5 micrometers. The second substrate part 124 is located between the stop layer structure 14 and the back surface 122, and a thickness of the second substrate part 124 is between 30 and 775 micrometers. In an embodiment, the stop layer structure 14 includes a dielectric stop layer 142, and the dielectric stop layer 142 is manufactured by performing an ion implantation process at a depth of the semiconductor substrate 12 and performing a high-temperature treatment process, such that the dielectric stop layer 142 is formed in a region for the ion implantation process. In a preferred embodiment, the stop layer structure 14 may include a dielectric stop layer 142 and a deep dielectric stop layer 141. The dielectric stop layer 142 is located between the deep dielectric stop layer 141 and the active surface 121, meaning that the dielectric stop layer 142 is closer to the active surface 121. The thicknesses of the deep dielectric stop layer 141 and the dielectric stop layer 142 are each, for example, between 50 nanometers and 1000 nanometers.

Next, as shown in FIG. 1B, an epitaxial layer 16, an active layer 18, a redistribution layer 20, and a first bonding layer 22 are sequentially formed on the active surface 121. In an embodiment, the epitaxial layer 16 is deposited on the active surface 121 via a metal-organic chemical vapor deposition (MOCVD) process. The thickness of the epitaxial layer 16 is, for example, between 50 and 500 nanometers. In an embodiment, the epitaxial layer 16 can prevent ion damage to the semiconductor substrate 12, thereby preventing defect formation. Active elements (for example, logic or memory MOSFETs, not shown in the figure) can be formed on the epitaxial layer 16. In an embodiment, the thickness of the redistribution layer 20 is, for example, about 10 micrometers. The first bonding layer 22 is formed on the redistribution layer 20 through, for example, a chemical vapor deposition (chemical vapor deposition, CVD) process. Thus, the manufacturing of the semiconductor wafer 1000 is completed. In the subsequent process, one of the manufactured semiconductor wafers 1000 is selected as the first semiconductor wafer 1000a (marked later), and another one of the semiconductor wafers 1000 is selected as the second semiconductor wafer 1000b (marked later).

As shown in FIG. 1C, a carrier board 30 is provided. The carrier board 30 is, for example, a silicon substrate, and a second bonding layer 32 is formed on the carrier board 30. The second bonding layer 32 is formed through, for example, a chemical vapor deposition process. The material of the second bonding layer 32 may be the same as or different from the material of the first bonding layer 22. The materials of the first bonding layer 22 and the second bonding layer 32 are, for example, silicon dioxide (SiO₂), silicon oxynitride (SiON), or silicon carbonitride (SiCN). Next, the first semiconductor wafer 1000a is inverted to bond the first bonding layer 22a of the first semiconductor wafer 1000a with the second bonding layer 32. In an embodiment, the first bonding layer 22a and the second bonding layer 32 may be bonded together through a melting bonding process, which further includes an annealing step. The bonded first bonding layer 22a and second bonding layer 32 are marked as a melted bonding layer 32′ in subsequent figures (for example, FIG. 1D).

Next, the second substrate part 124 of the inverted first semiconductor wafer 1000a and the stop layer structure 14 are removed to expose the first substrate part 123 of the first semiconductor wafer 1000a. The step of removing the second substrate part 124 and the stop layer structure 14 of the first semiconductor wafer 1000a includes performing a back surface grinding process on the inverted first semiconductor wafer 1000a to remove part of the second substrate part 124 from the side of the second substrate part 124 away from the stop layer structure 14. As shown in FIG. 1D, to avoid wafer warpage, the remaining or retained second substrate part 124′ has a thickness, for example, between 5 micrometers and 50 micrometers. Then, the remaining second substrate part 124′, the deep dielectric stop layer 141, and the dielectric stop layer 142 are sequentially removed, as shown in FIG. 1E, to expose the first substrate part 123 of the first semiconductor wafer 1000a.

Referring to FIGS. 1D and 1E, in an embodiment, the remaining second substrate part 124′ is removed using a low-cost wet etching process, where the etching selectivity ratio of the deep dielectric stop layer 141 to the second substrate part 124′ is between 1/10 and 1/300. The deep dielectric stop layer 141 can effectively delay chemical etching without further penetration. For example, a continuous dry etching process is used to remove the deep dielectric stop layer 141 and stops at the dielectric stop layer 142, where the etching selectivity ratio of the dielectric stop layer 142 to the deep dielectric stop layer 141 is between ⅕ and 1/100. For example, a continuous dry etching process is used to remove the dielectric stop layer 142 and stops at the first substrate part 123, where the etching selectivity ratio of the first substrate part 123 to the dielectric stop layer 142 is between ⅕ and 1/100.

Next, as shown in FIG. 1F, a plurality of wafer conductive structures 34 are formed to penetrate the first substrate part 123, the epitaxial layer 16, and the active layer 18 of the first semiconductor wafer 1000a to be connected to the redistribution layer 20. In an embodiment, the wafer conductive structure 34 includes, for example, through silicon vias (through silicon via, TSV), where the through silicon via has a width of 0.1-2 micrometers and a depth of 0.3-10 micrometers. An end of the wafer conductive structure 34 is connected to the redistribution layer 20, and the other end is exposed from the surface of the first substrate part 123. Referring to FIG. 1F, the method for manufacturing the wafer conductive structure 34 includes but is not limited to: forming multiple through holes 341 that penetrate the first substrate part 123, the epitaxial layer 18, and the active layer 18; sequentially conformally forming an insulating layer 342 and a barrier layer 343 on the side walls and bottom walls of the through holes 341; and disposing a conductive material 344 in the through holes 341, where the conductive material 344 is, for example, copper. A subsequent electrical connection to the wafer conductive structure 34 may be understood as an electrical connection to the conductive material 344.

Then, the first substrate part 123 is thinned, as shown in FIG. 1G, so that the wafer conductive structure 34 protrudes out of the thinned first substrate part 123′. In an embodiment, the wafer conductive structures 34 protrude out of the first substrate part 123′ by a height h1 between 50 and 500 nanometers. Next, as shown in FIG. 1H, a first bonding dielectric layer 36 is formed on the first substrate part 123′ of the first semiconductor wafer 1000a to cover the wafer conductive structures 34. The first bonding dielectric layer 36 is formed on the first substrate part 123′ through, for example, a chemical vapor deposition process, and the thickness of the first bonding dielectric layer 36 is between 50 and 1000 nanometers. The thickness of the first bonding dielectric layer 36 must be sufficient to cover the protruding wafer conductive structures 34, ensuring good step coverage (step coverage) capability. Then, as shown in FIG. 1I, the first bonding dielectric layer 36 is thinned through, for example, a chemical mechanical polishing (CMP) process to expose the wafer conductive structures 34, where approximately 200 nanometers of the first bonding dielectric layer 36 is removed to ensure the exposure of the wafer conductive structures 34. Based on consideration for the subsequent hybrid bonding technology, the top of the conductive material 344 of the wafer conductive structures 34 exposed from the thinned first bonding dielectric layer 36′ may optionally have a recessed structure 345, and the recessed structure 345 has a depth, for example, between 2 nanometers and 30 nanometers.

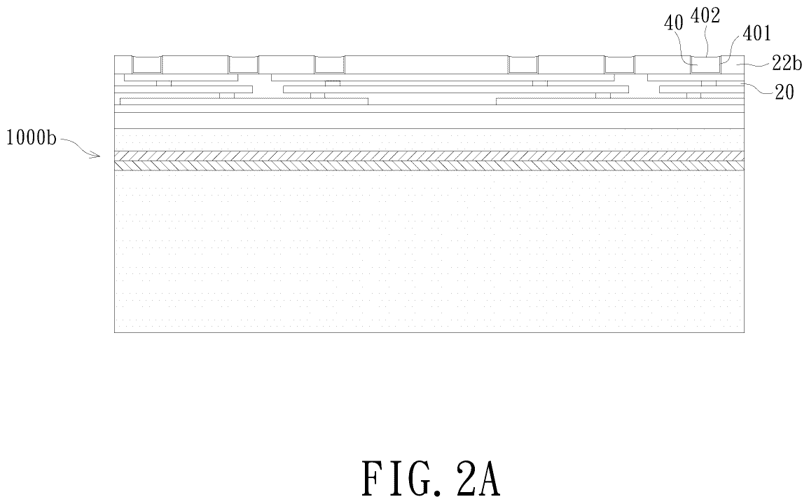

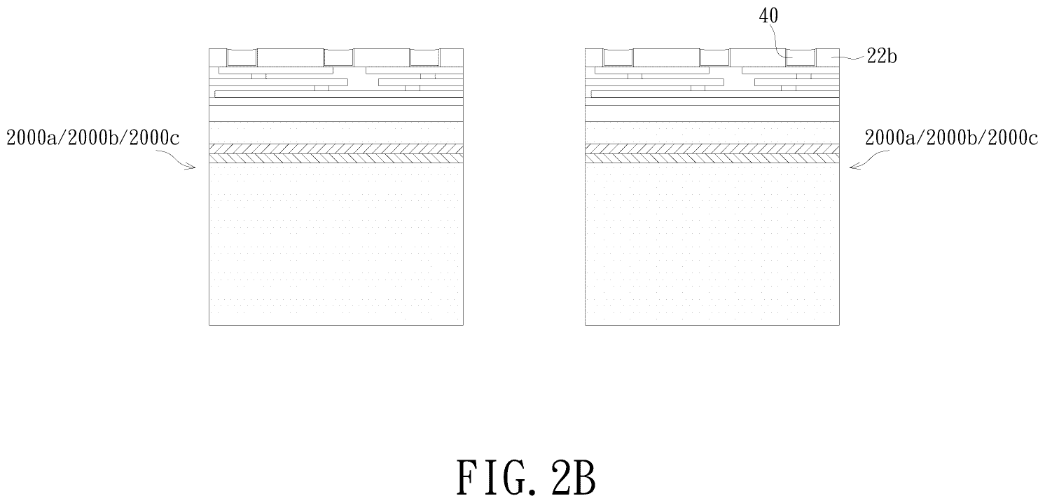

For the second semiconductor wafer 1000b, refer to FIGS. 2A and 2B, which are schematic flowcharts of manufacturing semiconductor dies according to an embodiment of the present invention. As shown in FIG. 2A, a plurality of conductive pillars 40 are disposed on the first bonding layer 22b of the second semiconductor wafer 1000b, and the conductive pillars 40 are electrically connected to the redistribution layer 20. In an embodiment, a barrier layer 401 is formed on the side walls and bottoms of the conductive pillars 40. Based on consideration for the subsequent hybrid bonding technology, a recessed structure 402 is also formed at the end of the conductive pillars 40 away from the redistribution layer 20. Then, die sawing is performed on the second semiconductor wafer 1000b with the conductive pillars 40 formed on the first bonding layer 22b, as shown in FIG. 2B, to form the first batch of semiconductor dies 2000a, the second batch of semiconductor dies 2000b, and the third batch of semiconductor dies 2000c that are to be stacked. The thicknesses of the first batch of semiconductor dies 2000a, the second batch of semiconductor dies 2000b, and the third batch of semiconductor dies 2000c are, for example, between 50 micrometers and 800 micrometers. Furthermore, as the number of stacked layers of the semiconductor stack structure 3000A (marked in FIG. 1V) with ultra thin dies increases, there are additional batches of semiconductor dies, such as the fourth batch and the fifth batch.

Based on the description of the method for manufacturing a semiconductor stack structure with ultra thin dies in the first embodiment, as shown in FIG. 1J, the first batch of semiconductor dies 2000a are inverted, such that the first bonding layer 22b of the first batch of semiconductor dies 2000a is opposite the thinned first bonding dielectric layer 36′, and the conductive pillars 40 in the first bonding layer 22b of the first batch of semiconductor dies 2000a respectively correspond to the wafer conductive structures 34. The first bonding layer 22b of the first batch of semiconductor dies 2000a is bonded with the thinned first bonding dielectric layer 36′ using the hybrid bonding technology, where the conductive pillars 40 respectively contact and are electrically connected to the wafer conductive structures 34. FIG. 1J illustrates two first batches of semiconductor dies 2000a as an example, which, however, are not limited herein, and there are gaps G between adjacent first batches of semiconductor dies 2000a. It can be understood that the first batch of semiconductor dies 2000a and the first semiconductor wafer 1000a are stacked face-to-face (face to face) in a Chip-on-Wafer (Chip-on-Wafer, CoW) stacking pattern.

Then, the back surface grinding process is performed on the second substrate part 124 of the inverted first batch of semiconductor dies 2000a to remove part of the second substrate part 124 from the side of the second substrate part 124 away from the stop layer structure 14. In an embodiment, as shown in FIG. 1K, the thickness of the remaining second substrate part 124′ is, for example, between 5 micrometers and 50 micrometers, such that a distance (that is, the gap height H) between the back surface of the remaining second substrate part 124′ and the first bonding dielectric layer 36′ is between 15 micrometers and 70 micrometers. Considering issues such as wafer warpage and total thickness variation (TTV), the thickness of the remaining second substrate part 124′ of the first batch of semiconductor dies 2000a should not be less than 5 micrometers, so as to avoid excessive grinding and affecting yield. Next, still referring to FIG. 1K, on the first bonding dielectric layer 36′, a first packaging colloid 42a is formed to cover the first batch of semiconductor dies 2000a and fill up gaps G between the first batch of semiconductor dies 2000a. In an embodiment, the first packaging colloid 42a is formed through, for example, a chemical vapor deposition process, and the first packaging colloid 42a includes, for example, silicon dioxide. Because the gap height H is between 15 micrometers and 70 micrometers, the first packaging colloid 42a can easily fill the gaps G through the chemical vapor deposition process, achieving ideal gap-filling properties.

Based on the foregoing description, part of the first packaging colloid 42a is removed and the remaining second substrate part 124′ and the stop layer structure 14 of the first batch of semiconductor dies 2000a are removed, to expose the first substrate part 123 of the first batch of semiconductor dies 2000a. Referring to FIGS. 1K and 1L, the removal steps may sequentially include but are not limited to: grinding the portion of the first packaging colloid 42a above the second substrate part 124′ via a chemical mechanical polishing process; removing the second substrate part 124′ using, for example, a wet etching process and simultaneously removing part of the first packaging colloid 42a; removing the deep dielectric stop layer 141 using, for example, a dry etching process and simultaneously removing part of the first packaging colloid 42a; and removing the dielectric stop layer 142 using, for example, a dry etching process and simultaneously removing part of the first packaging colloid 42a to expose the first substrate part 123 of the first batch of semiconductor dies 2000a. In an embodiment, in the above wet etching or dry etching process, the etching selectivity ratio of the deep dielectric stop layer 141 to the second substrate part 124′ is between 1/10 and 1/300; the etching selectivity ratio of the dielectric stop layer 142 to the deep dielectric stop layer 141 is between ⅕ and 1/100; and the etching selectivity ratio of the first substrate part 123 to the dielectric stop layer 142 is between ⅕ and 1/100. When the second substrate part 124′ is removed through the wet etching process, the high etching selectivity ratio helps avoid issues such as wafer warpage and total thickness variation (TTV).

Next, as shown in FIG. 1M, a plurality of first die conductive structures 44a are formed to penetrate the first substrate part 123, the epitaxial layer 16, and the active layer 18 of the first batch of semiconductor dies 2000a to be connected to the redistribution layer 20. The first die conductive structure 44a has, for example, a through silicon via (TSV), and one end of the first die conductive structure 44a is connected to the redistribution layer 20 and the other end is exposed from the surface of the first substrate part 123. The first die conductive structures 44a include an insulating layer 442, a barrier layer 443, and a conductive material 444 sequentially disposed in the through hole 441. The structure and manufacturing method of the first die conductive structures 44a correspond to the structure and manufacturing method of the wafer conductive structures 34, and are not repeated herein. Then, the first substrate part 123 and the first packaging colloid 42a are thinned, as shown in FIG. 1N, such that the first die conductive structures 44a protrude out of the thinned first substrate part 123′. In an embodiment, the first die conductive structures 44a protrude out of the first substrate part 123′ by a height h2 between 100 and 600 nanometers. A subsequent electrical connection to the first die conductive structure 44a may be understood as an electrical connection to the conductive material 444.

Next, as shown in FIG. 1O, a second bonding dielectric layer 46 is formed on the first packaging colloid 42a and the first substrate part 123′ of the first batch of semiconductor dies 2000a to cover the first die conductive structures 44a. The second bonding dielectric layer 46 is formed through, for example, a chemical vapor deposition process on the first substrate part 123′ and the first packaging colloid 42a, and the thickness of the second bonding dielectric layer 46 is between 100 and 1000 nanometers. The thickness of the second bonding dielectric layer 46 should be sufficient to cover the protruding first die conductive structures 44a, ensuring good step coverage capability. Then, as shown in FIG. 1P, the second bonding dielectric layer 46 is thinned through, for example, a chemical mechanical polishing (CMP) process to expose the first die conductive structures 44a. Based on consideration for the subsequent hybrid bonding technology, the top of the conductive material 444 of the first die conductive structures 44a exposed from the thinned second bonding dielectric layer 46′ optionally has a recessed structure 445, where the recessed structure 445 has a depth, for example, between 3 nanometers and 30 nanometers. Thus, the stacking of the first batch of semiconductor dies 2000a is completed.

Then, the second batch of semiconductor dies 2000b can be continuously stacked. As shown in FIG. 1Q, the second batch of semiconductor dies 2000b are inverted, such that the first bonding layer 22b of the second batch of semiconductor dies 2000b and the second bonding dielectric layer 46′ are opposite each other and bonded together through the hybrid bonding technology, where the conductive pillars 40 of the second batch of semiconductor dies 2000b respectively correspond to and are electrically connected to the first die conductive structures 44a. Next, corresponding to the steps for the first batch of semiconductor dies 2000a, a back surface grinding process is performed on the second substrate part 124 of the second batch of semiconductor dies 2000b to thin the second substrate part 124. A second packaging colloid 42b (as shown in FIG. 1R) is formed on the second bonding dielectric layer 46′ to cover the second batch of semiconductor dies 2000b and fill up the gaps G between the second batch of semiconductor dies 2000b. Part of the second packaging colloid 42b is removed and the second substrate part 124 and the stop layer structure 14 of the second batch of semiconductor dies 2000b are also removed, to expose the first substrate part 123 of the second batch of semiconductor dies 2000b. Referring to FIG. 1R, a plurality of second die conductive structures 44b are formed to penetrate the first substrate part 123, the epitaxial layer 16, and the active layer 18 of the second batch of semiconductor dies 2000b, to be connected to the redistribution layer 20. The first substrate part 123 and part of the second packaging colloid 42b are thinned, allowing the second die conductive structures 44b to protrude out of the first substrate part 123′ of the second batch of semiconductor dies 2000b. Next, a third bonding dielectric layer 48 is formed on the first substrate part 123′ of the second batch of semiconductor dies 2000b and the second packaging colloid 42b, to cover the second die conductive structures 44b. The third bonding dielectric layer 48 is thinned, such that the second die conductive structures 44b are exposed from the surface of the thinned third bonding dielectric layer 48′, thereby completing the stacking of the second batch of semiconductor dies 2000b. The steps of removing the second substrate part 124 and the stop layer structure 14 of the second batch of semiconductor dies 2000b correspond to the steps or methods for removing the first batch of semiconductor dies 2000a. Additionally, the formation method, structural features, and achievable effects of the second die conductive structures 44b and the third bonding dielectric layer 48 correspond to those of the first die conductive structures 44a and the second bonding dielectric layer 46, as previously disclosed, and are not repeated herein.

Furthermore, still referring to FIG. 1R, the stacking steps of the first batch of semiconductor dies 2000a/second batch of semiconductor dies 2000b can be repeated for the stacking of the next batch of semiconductor dies (for example, the third batch of semiconductor dies 2000c). The first bonding layer 22b of the third batch of semiconductor dies 2000c and the third bonding dielectric layer 48′ are opposite and bonded together through the hybrid bonding technology, and the conductive pillars 40 of the third batch of semiconductor dies 2000c respectively correspond to and are electrically connected to the second die conductive structures 44b. A third packaging colloid 42c is formed on the third bonding dielectric layer 48′ to cover the third batch of semiconductor dies 2000c and fill up the gaps between the third batch of semiconductor dies 2000c. A plurality of third die conductive structures 44c penetrate the first substrate part 123′, the epitaxial layer 16, and the active layer 18 of the third batch of semiconductor dies 2000c to be connected to the redistribution layer 20, and the third die conductive structures 44c protrude out of the first substrate part 123′. A fourth bonding dielectric layer 50 is formed on the first substrate part 123′ of the third batch of semiconductor dies 2000c and the third packaging colloid 42c to cover the third die conductive structures 44c, and the fourth bonding dielectric layer 50′ is thinned to expose the third die conductive structures 44c. This process is repeated multiple times to complete the stacking of the predetermined number of semiconductor die layers.

Then, as shown in FIG. 1S, a dummy carrier board 60 is provided, and a third bonding layer 62 is formed on the dummy carrier board 60. Next, the third bonding layer 62 is bonded with the fourth bonding dielectric layer 50′ on the top layer of the semiconductor dies (for example, the third batch of semiconductor dies 2000c). In an unillustrated embodiment, if the top layer of semiconductor dies is the second batch of semiconductor dies 2000b, the third bonding layer 62 of the dummy carrier board 60 is bonded with the third bonding dielectric layer 48′. In the top layer of the semiconductor dies, die conductive structures (for example, TSV) are still formed, which is based on consideration for heat dissipation. Also, the combination of the dummy carrier board 60 with the bonding dielectric layer of the top layer ensures that the entire stack structure has a thickness of about 700 micrometers, maintaining overall structural strength.

After the dummy carrier board 60 is bounded, the entire stack structure is inverted, such that the dummy carrier board 60 is located below and the carrier board 30 is located above. Then, as shown in FIG. 1T, the carrier board 30 located above is removed, to expose the melting bonding layer 32′. Next, as shown in FIG. 1U, a plurality of grooves 64 are formed in the melting bonding layer 32′ to expose the redistribution layer 20 of the first semiconductor wafer 1000a. In an embodiment, the carrier board 30 may be removed using a wet etching process or a delamination technique; the grooves 64 may be formed using photolithography/etching processes. Then, a plurality of solder balls 66 are respectively placed in the grooves 64, and the solder balls 66 are electrically connected to the redistribution layer 20. In an embodiment, the solder balls 66 may be formed using processes such as sputtering, photolithography, electrochemical plating (ECP), and wet etching. Finally, die sawing is performed at the positions of the stacked first batch of semiconductor dies 2000a, second batch of semiconductor dies 2000b, and third batch of semiconductor dies 2000c to complete the semiconductor stack structure 3000A with ultra thin dies as shown in FIG. 1V. As shown in FIG. 1U, the stack structure may be mounted on a frame 68, and then die sawing is performed using plasma cutting or mechanical cutting.

The semiconductor substrate 12 may be, for example, a silicon substrate (silicon substrate), an epitaxial silicon substrate (epitaxial silicon substrate), a silicon germanium substrate (silicon germanium substrate), a silicon carbide substrate (silicon carbide substrate), or a silicon on insulation (silicon on insulation, SOI) substrate.

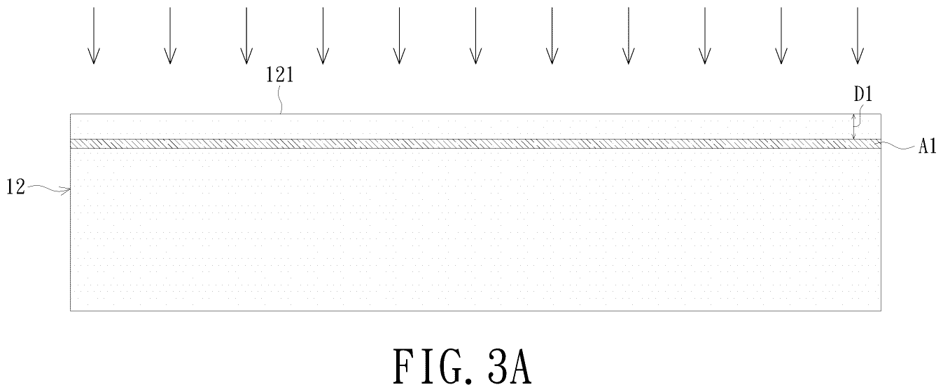

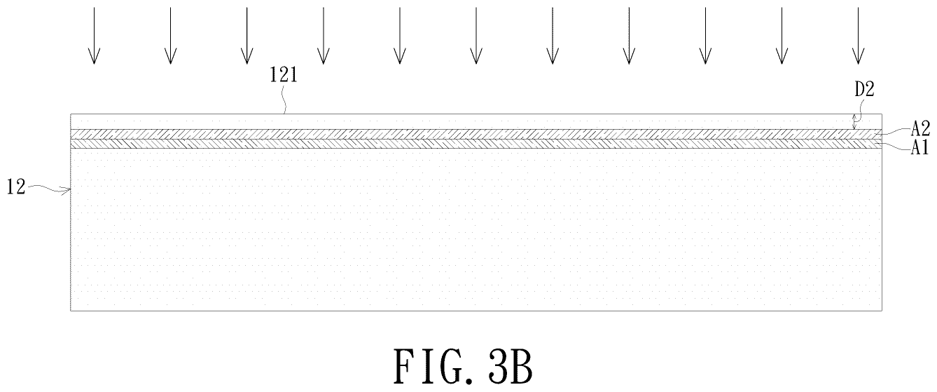

In an embodiment, FIGS. 3A and 3B are schematic cross-sectional views of a method for manufacturing a stop layer structure according to an embodiment of the present invention. As shown in FIG. 3A, a first ion implantation process is performed at a first depth D1 of the semiconductor substrate 12, where the first depth D1 of the region A1 for the first ion implantation process is, for example, approximately 1 to 5 micrometers from the active surface 121. Next, as shown in FIG. 3B, a second ion implantation process is performed at a second depth D2 of the semiconductor substrate 12, where the second depth D2 is different from the first depth D1, and the second depth D2 is less than the first depth D1, meaning that the region A2 for the second ion implantation process is closer to the active surface 121. The element used for the first ion implantation process and the element used for the second ion implantation process are selected from boron, carbon, nitrogen, fluorine, phosphorus, argon, and arsenic, and the element used for the first ion implantation process and the element used for the second ion implantation process are different. Next, a high-temperature treatment process is performed, such that a deep dielectric stop layer 141 (as shown in FIG. 1A) is formed in the region A1 for the first ion implantation process and a dielectric stop layer 142 (as shown in FIG. 1A) is formed in the region A2 for the second ion implantation process.

In the method for manufacturing a semiconductor stack structure with ultra thin dies according to the first embodiment of the present invention, the first batch of semiconductor dies 2000a and the first semiconductor wafer 1000a are stacked face-to-face in a Chip-on-Wafer (Chip-on-Wafer, CoW) manner. The benefit of this Chip-on-Wafer approach is that die probing (Chip Probing, CP) can be performed first to obtain known good dies (Known Good Die) that pass the electrical function test (Test), ensuring high-yield production. Additionally, the second batch of semiconductor dies 2000b and the first batch of semiconductor dies 2000a, or the third batch of semiconductor dies 2000c and the second batch of semiconductor dies 2000b, are also stacked face-to-face continuously to form a multilayer 3D die stack structure. Because the second substrate part 124 of each batch of semiconductor dies (for example, the first batch of semiconductor dies 2000a, second batch of semiconductor dies 2000b, or third batch of semiconductor dies 2000c) has been partially ground through the back surface grinding process, the gap height H is between 15 micrometers and 70 micrometers. This facilitates gap filling of the packaging colloid through the chemical vapor deposition process, achieving ideal gap-filling performance.

Moreover, in the method for manufacturing a semiconductor stack structure with ultra thin dies according to the first embodiment, because the stop layer structure 14 includes double or multiple layers, such as the deep dielectric stop layer 141 and the dielectric stop layer 142, a robust etching mechanism can be formed, overcoming issues such as wafer warping and total thickness variation (TTV). Furthermore, during the process of removing the second substrate part 124, the deep dielectric stop layer 141, and the dielectric stop layer 142 through sequential wet etching and dry etching processes, because the second substrate part 124, the deep dielectric stop layer 141, and the dielectric stop layer 142 have different etching selectivity ratios, a large process window (process window) is provided, allowing for the manufacturing of a stable 3D die stack structure.

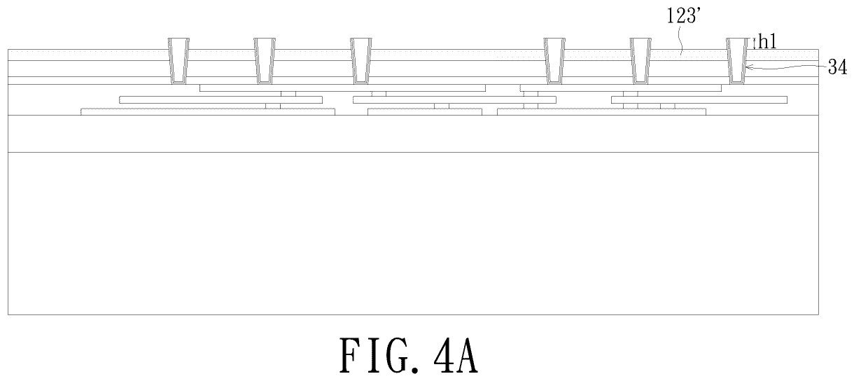

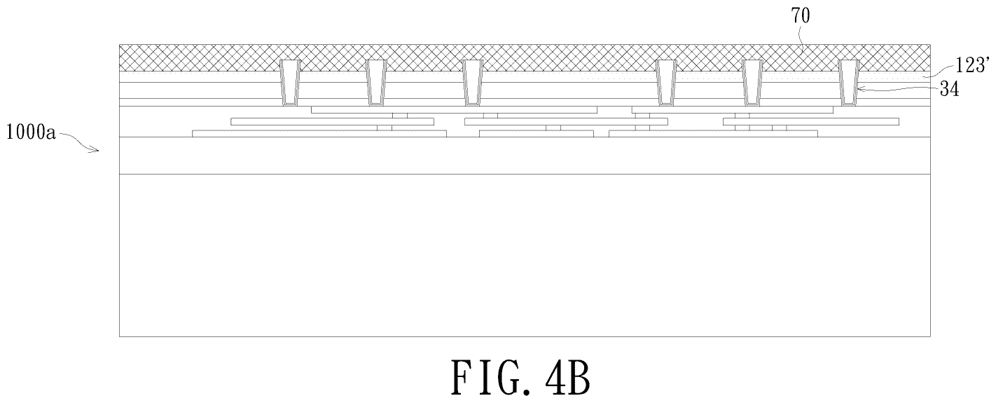

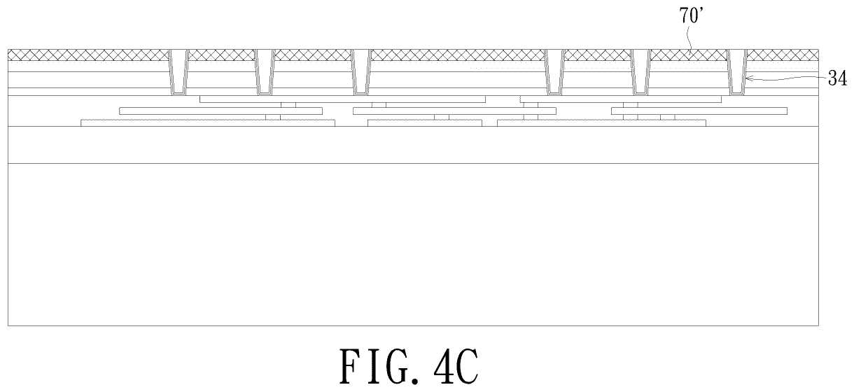

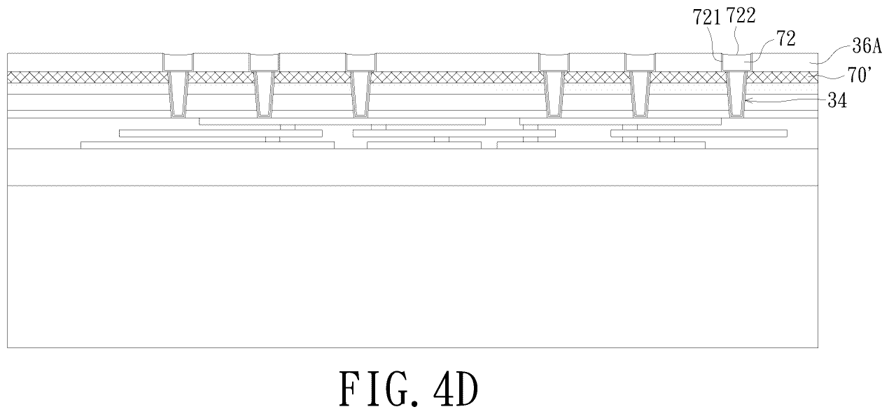

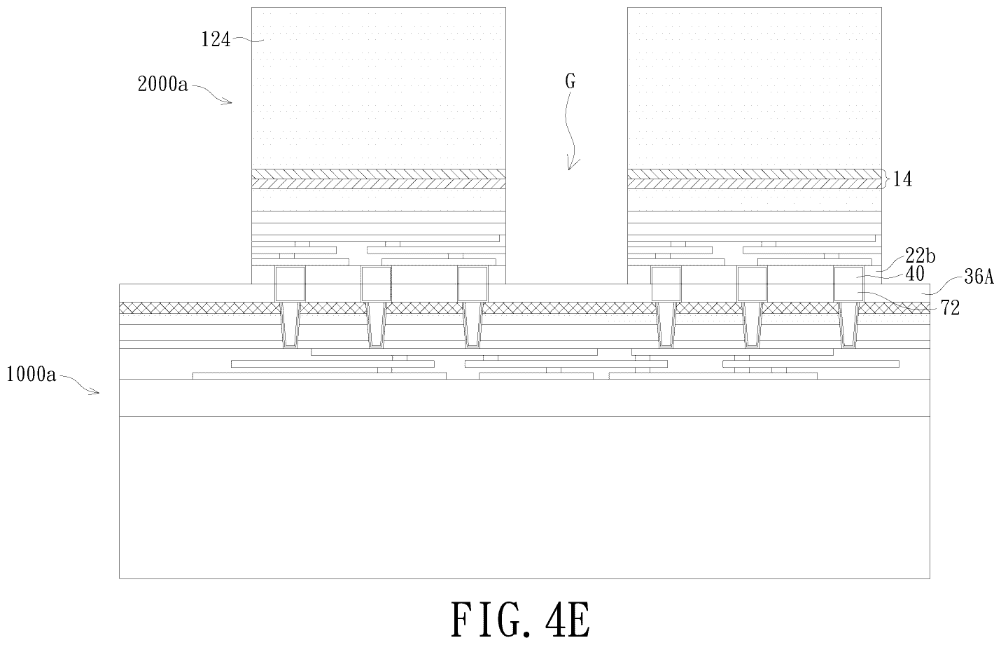

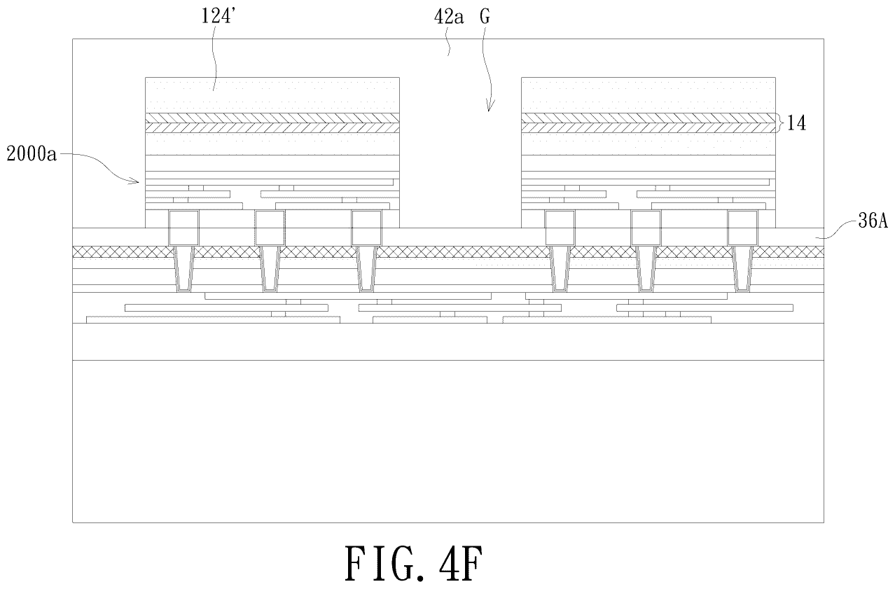

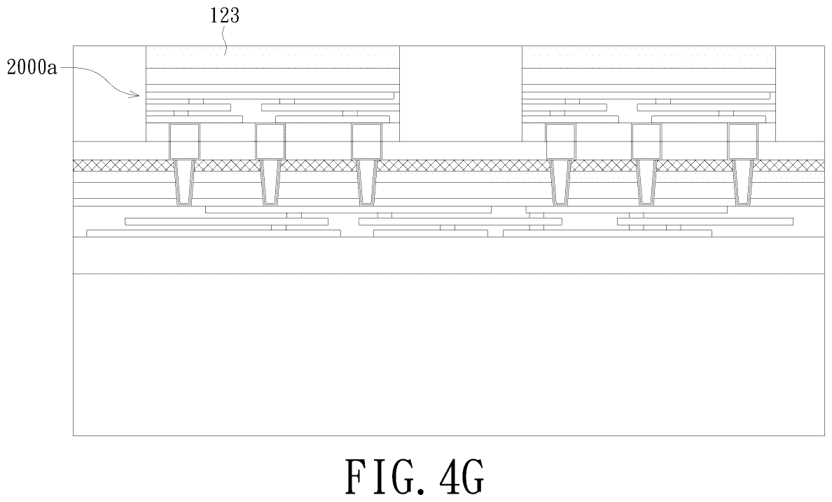

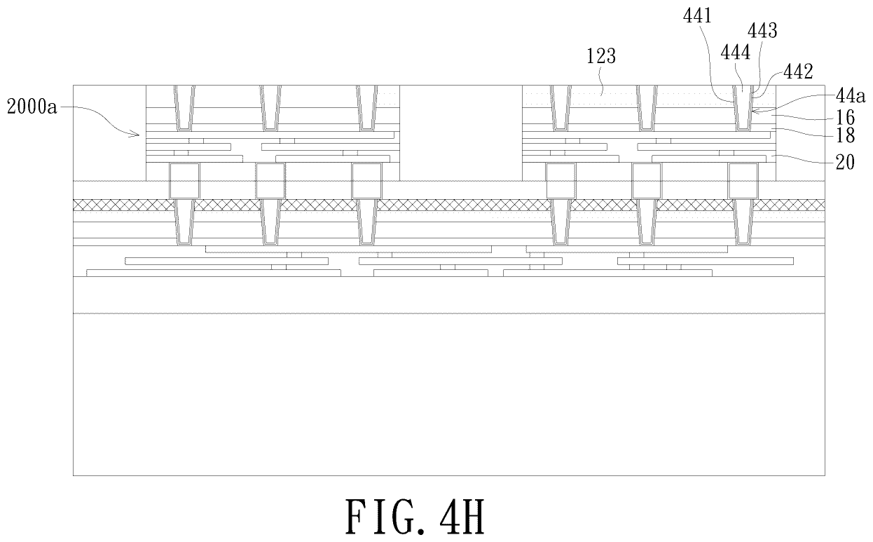

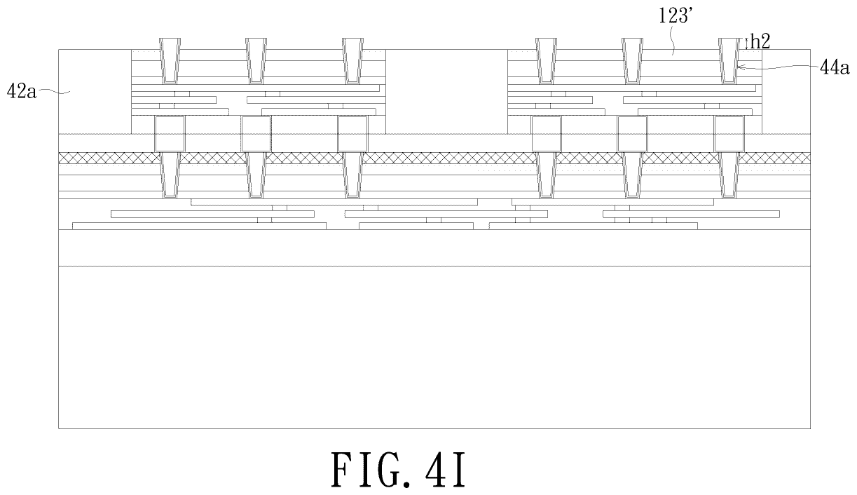

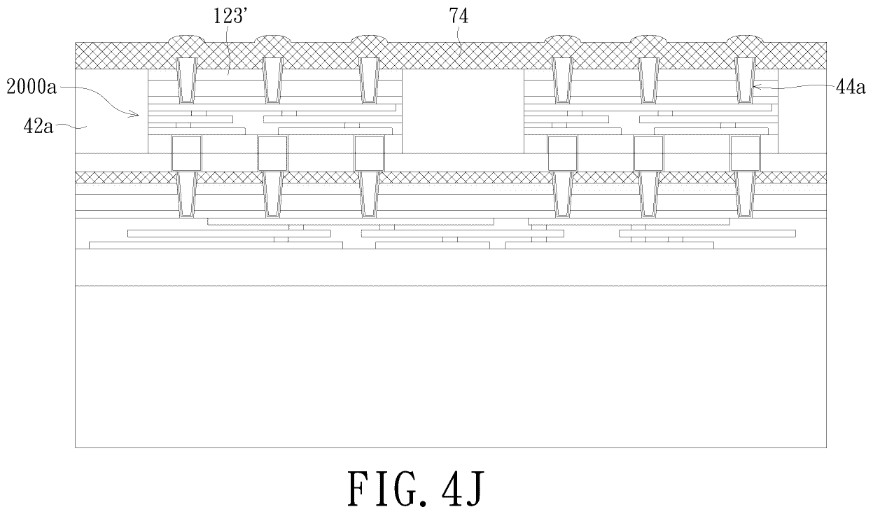

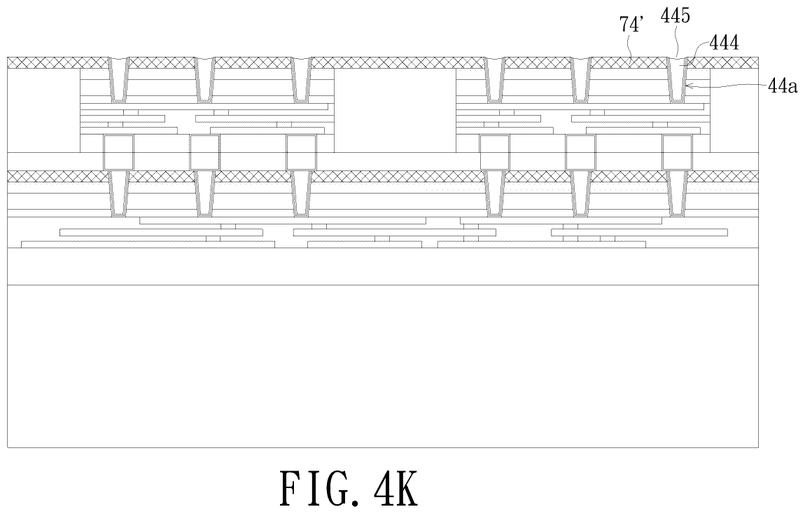

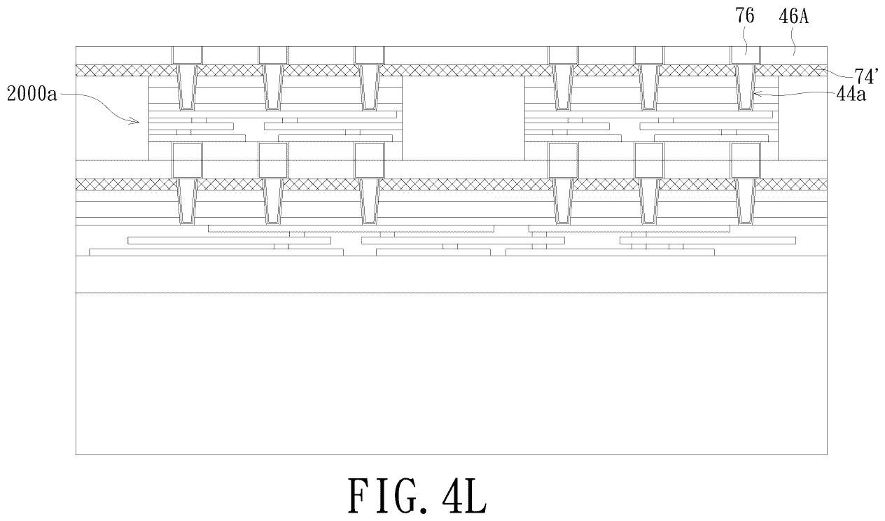

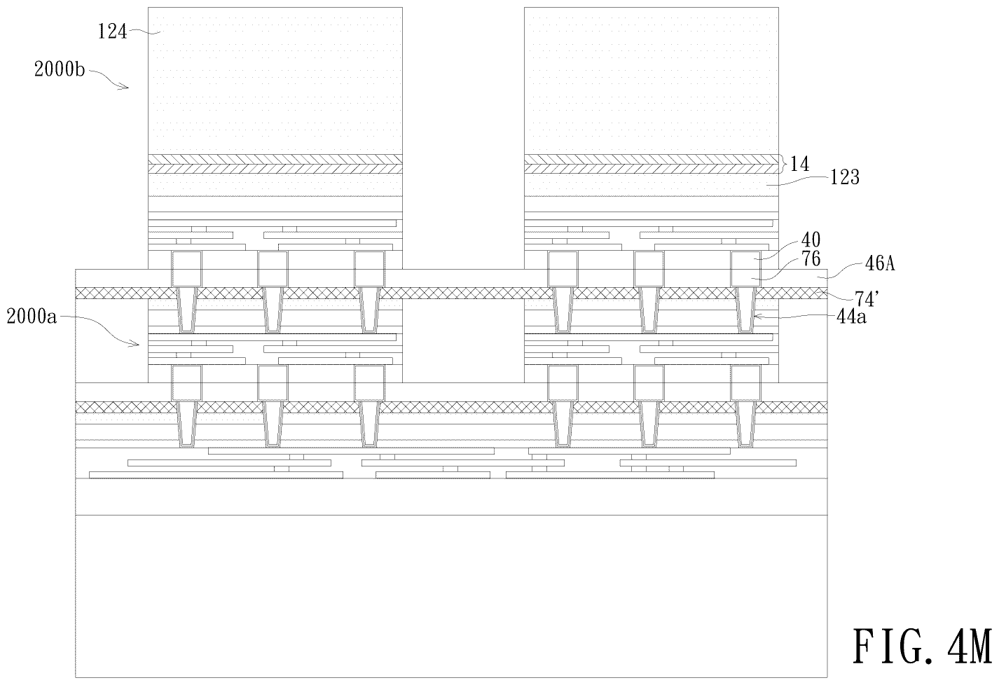

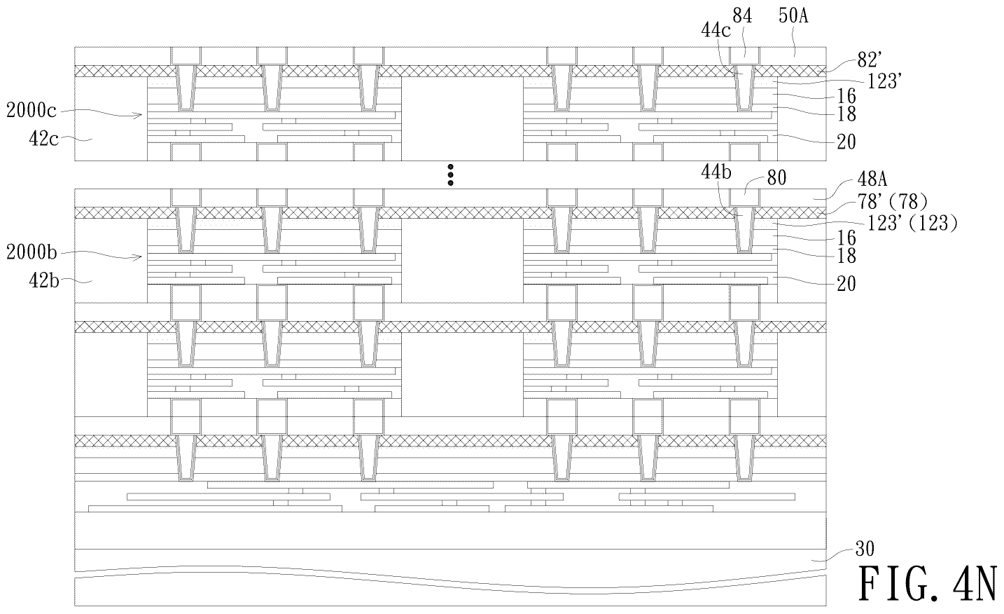

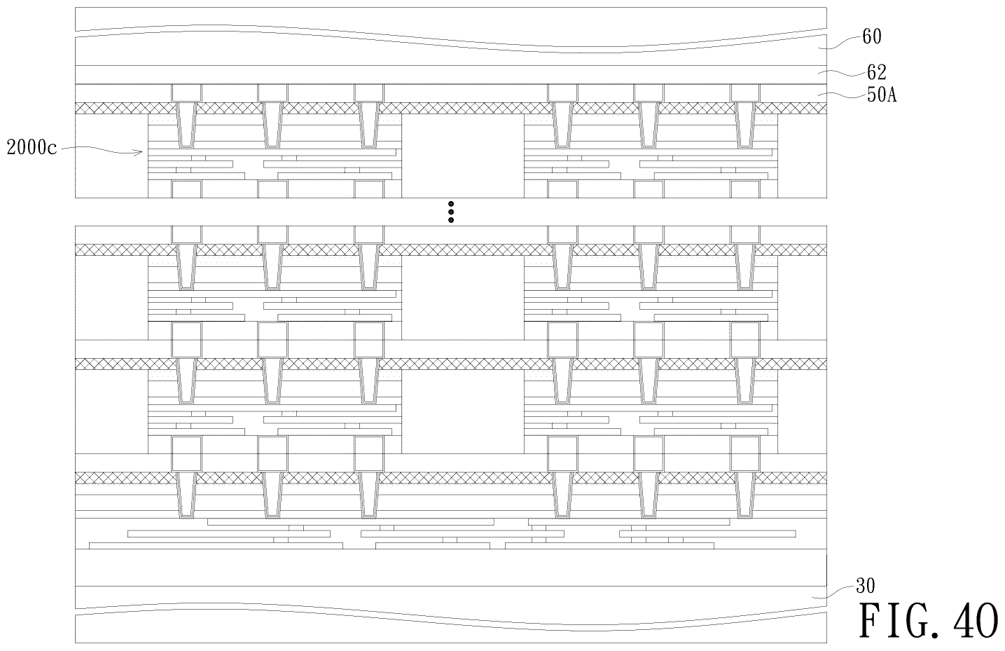

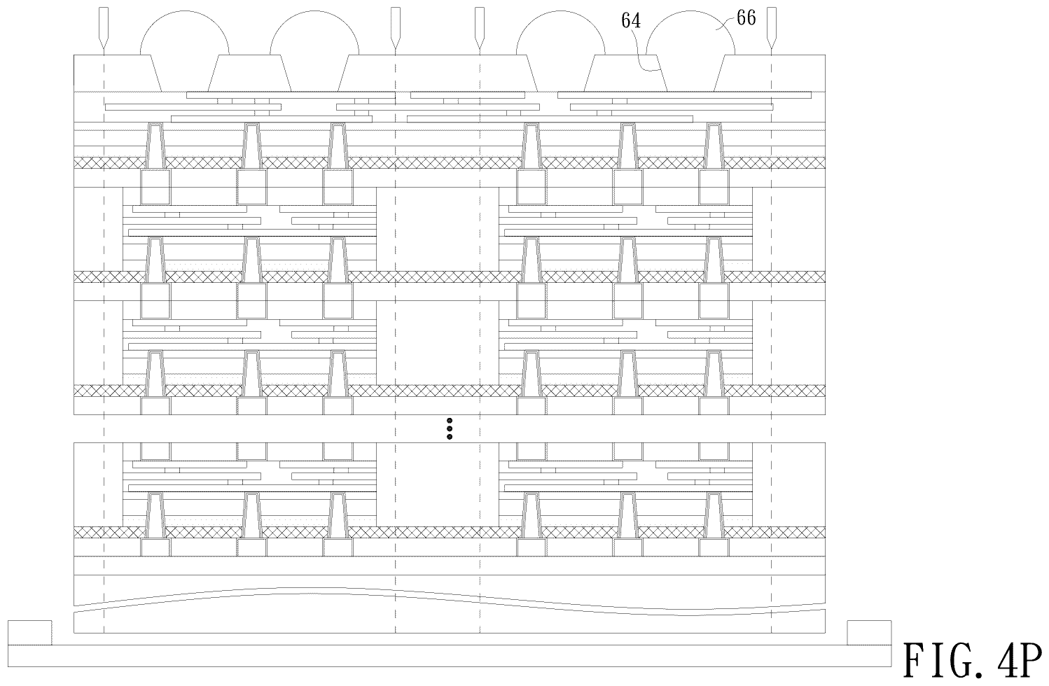

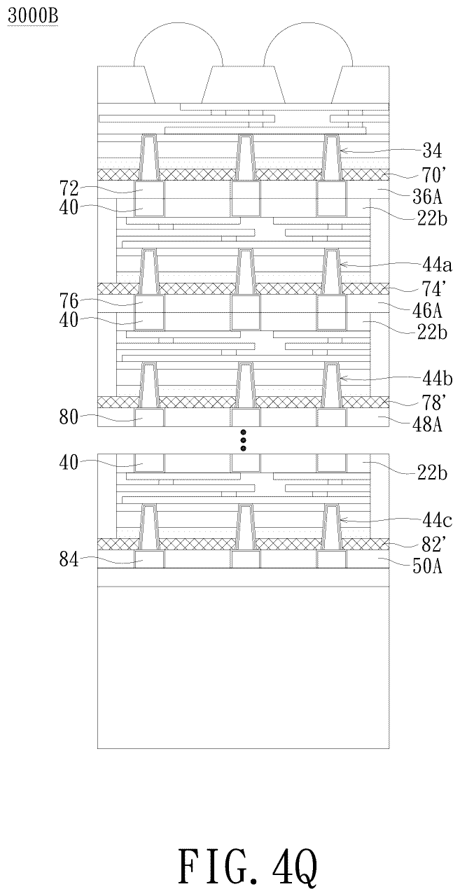

FIGS. 4A to 4Q are schematic cross-sectional views of some stages of the method for manufacturing a semiconductor stack structure with ultra thin dies according to a second embodiment of the present invention. According to the second embodiment, the preliminary stages of the method for manufacturing the semiconductor stack structure with ultra thin dies are shown in FIGS. 1A to 1G and are not repeated herein. As shown in FIG. 4A (corresponding to FIG. 1G), the wafer conductive structures 34 protrude out of the first substrate part 123′. In an embodiment, the height h1 of the wafer conductive structures 34 protruding out of the first substrate part 123′ is between 50 and 500 nanometers. Next, as shown in FIG. 4B, a first dielectric layer 70 is formed on the first substrate part 123′ of the first semiconductor wafer 1000a to cover the wafer conductive structures 34. Then, as shown in FIG. 4C, the first dielectric layer 70 is thinned, such that the wafer conductive structures 34 are exposed from the surface of the thinned first dielectric layer 70′.

Then, as shown in FIG. 4D, a first bonding dielectric layer 36A is formed on the first dielectric layer 70′ and the wafer conductive structures 34, where a plurality of first conductive blocks 72 penetrate the first bonding dielectric layer 36A, and the first conductive blocks 72 are electrically connected to the wafer conductive structures 34, respectively. In an embodiment, a barrier layer 721 is formed on the side walls and bottoms of the first conductive blocks 72; and the first conductive blocks 72, for example, are copper blocks. The first bonding dielectric layer 36A and the first conductive blocks 72 are formed through processes such as chemical vapor deposition, photolithography, etching, sputtering, electrochemical plating, and chemical mechanical polishing, to serve as a bonding layer for hybrid bonding with semiconductor dies. Also based on consideration for the subsequent hybrid bonding technology, the exposed top end of the first conductive block 72 optionally has a recessed structure 722, and the recessed structure 722 has a depth, for example, between 2 nanometers and 30 nanometers.

Next, the first batch of semiconductor dies 2000a, the second batch of semiconductor dies 2000b, the third batch of semiconductor dies 2000c, and subsequent more batches of semiconductor dies are provided for stacking. The manufacturing of each batch of semiconductor dies is referenced in FIGS. 2A and 2B and is not repeated herein. As shown in FIG. 4E, the first batch of semiconductor dies 2000a are inverted, such that the first bonding layer 22b of the first batch of semiconductor dies 2000a and the first bonding dielectric layer 36A on the first semiconductor wafer 1000a are opposite, and the conductive pillars 40 in the first bonding layer 22b of the first batch of semiconductor dies 2000a respectively correspond to the first conductive blocks 72 in the first bonding dielectric layer 36A. Next, the first bonding layer 22b of the first batch of semiconductor dies 2000a is bonded with the first bonding dielectric layer 36A using the hybrid bonding technology, where the first conductive blocks 72 in the first bonding dielectric layer 36A respectively correspond to and are electrically connected to the conductive pillars 40 of the first batch of semiconductor dies 2000a. FIG. 4E illustrates two first batches of semiconductor dies 2000a as an example, which, however, are not limited herein, and there are gaps G between adjacent first batches of semiconductor dies 2000a.

Then, a back surface grinding process is performed on the second substrate part 124 of the inverted first batch of semiconductor dies 2000a, to remove part of the second substrate part 124 from the side of the second substrate part 124 away from the stop layer structure 14, thus obtaining the remaining (or thinned) second substrate part 124′, as shown in FIG. 4F. Next, on the first bonding dielectric layer 36A, a first packaging colloid 42a is formed to cover the first batch of semiconductor dies 2000a and fill up gaps G between the first batch of semiconductor dies 2000a. The effects achieved by the remaining second substrate part 124′ and the method for forming the first packaging colloid 42a have been disclosed in the first embodiment and are not repeated herein.

Next, part of the first packaging colloid 42a is removed and the remaining second substrate part 124′ and the stop layer structure 14 of the first batch of semiconductor dies 2000a are removed, as shown in FIG. 4G, to expose the first substrate part 123 of the first batch of semiconductor dies 2000a. The methods or steps for removal have been disclosed in the first embodiment and are not repeated herein. Next, as shown in FIG. 4H, a plurality of first die conductive structures 44a are formed to penetrate the first substrate part 123, the epitaxial layer 16, and the active layer 18 of the first batch of semiconductor dies 2000a to be connected to the redistribution layer 20. The first die conductive structure 44a has, for example, a through silicon via (TSV), and one end of the first die conductive structure 44a is connected to the redistribution layer 20 and the other end is exposed from the surface of the first substrate part 123. The first die conductive structures 44a include an insulating layer 442, a barrier layer 443, and a conductive material 444 sequentially disposed in through holes 441. Their manufacturing method corresponds to the manufacturing method of the wafer conductive structures 34 and is not repeated herein. Then, the first substrate part 123 and the first packaging colloid 42a are thinned, as shown in FIG. 4I, such that the first die conductive structures 44a protrude out of the thinned first substrate part 123′. In an embodiment, the first die conductive structures 44a protrude out of the first substrate part 123′ by a height h2 between 100 and 600 nanometers.

Next, as shown in FIG. 4J, a second dielectric layer 74 is formed on the first packaging colloid 42a and the first substrate part 123′ of the first batch of semiconductor dies 2000a, covering the first die conductive structures 44a. Then, as shown in FIG. 4K, the second dielectric layer 74 is thinned through, for example, chemical mechanical polishing (CMP), such that the first die conductive structures 44a are exposed from the surface of the thinned second dielectric layer 74′, where the exposed top end of the conductive material 444 of the first die conductive structure 44a optionally has a recessed structure 445, and the recessed structure 445 has a depth, for example, between 3 nanometers and 30 nanometers. As shown in FIG. 4L, a second bonding dielectric layer 46A is formed on the second dielectric layer 74′ and the first die conductive structures 44a, where a plurality of second conductive blocks 76 penetrate the second bonding dielectric layer 46A, and the second conductive blocks 76 are electrically connected to the first die conductive structures 44a, respectively. Thus, the stacking of the first batch of semiconductor dies 2000a is completed.

Next, the stacking of the next batch of semiconductor dies (for example, the second batch of semiconductor dies 2000b) continues. As shown in FIG. 4M, the stacking steps of the first batch of semiconductor dies 2000a can be repeated for the stacking of the second batch of semiconductor dies 2000b. For example, the second batch of semiconductor dies 2000b is bonded with the second bonding dielectric layer 46A using the hybrid bonding technology, and the conductive pillars 40 of the second batch of semiconductor dies 2000b respectively correspond to and are electrically connected to the second conductive blocks 76 in the second bonding dielectric layer 46A. A back surface grinding process is performed on the second substrate part 124 of the second batch of semiconductor dies 2000b to thin the second substrate part 124. A second packaging colloid 42b (marked in FIG. 4N) is formed on the second bonding dielectric layer 46A to cover the second batch of semiconductor dies 2000b and fill up the gaps between the second batch of semiconductor dies 2000b. Part of the second packaging colloid 42b and the second substrate part 124 and stop layer structure 14 of the second batch of semiconductor dies 2000b are removed to expose the first substrate part 123 of the second batch of semiconductor dies 2000b. Refer to FIG. 4N, where a plurality of second die conductive structures 44b are formed to penetrate the first substrate part 123, the epitaxial layer 16, and the active layer 18 of the second batch of semiconductor dies 2000b to be connected to the redistribution layer 20, and the first substrate part 123 of the second batch of semiconductor dies 2000b is thinned, such that the second die conductive structures 44b protrude out of the first substrate part 123′. A third dielectric layer 78 is formed on the second packaging colloid 42b and the first substrate part 123′ of the second batch of semiconductor dies 2000b and the third dielectric layer 78 is thinned, such that the second die conductive structures 44b are exposed from the surface of the thinned third dielectric layer 78′. A third bonding dielectric layer 48A is formed on the third dielectric layer 78′ and the second die conductive structures 44b, where a plurality of third conductive blocks 80 penetrate the third bonding dielectric layer 48A, and the third conductive blocks 80 are electrically connected to the second die conductive structures 44b, respectively. Thus, the stacking of the second batch of semiconductor dies 2000b is completed.

Next, the stacking of the next batch of semiconductor dies (for example, the third batch of semiconductor dies 2000c) continues. After the stacking steps of the second batch of semiconductor dies 2000b are repeated for the stacking of the third batch of semiconductor dies 2000c, refer to FIG. 4N, where the third packaging colloid 42c covers the third batch of semiconductor dies 2000c. A plurality of third die conductive structures 44c penetrate the first substrate part 123′, the epitaxial layer 16, and the active layer 18 of the third batch of semiconductor dies 2000c to be connected to the redistribution layer 20. A fourth dielectric layer 82′ is formed on the third packaging colloid 42c and the first substrate part 123′ and between the third die conductive structures 44c. A fourth bonding dielectric layer 50A is formed on the third die conductive structures 44c and the fourth dielectric layer 82′, where a plurality of fourth conductive blocks 84 penetrate the fourth bonding dielectric layer 50A and are electrically connected to the third die conductive structures 44c, respectively. Thus, the stacking of the third batch of semiconductor dies 2000c is completed. This process is repeated multiple times to complete the stacking of the predetermined number of semiconductor die layers.

Then, as shown in FIG. 4O, the third bonding layer 62 of the dummy carrier board 60 is bonded with the fourth bonding dielectric layer 50A on the top layer of semiconductor dies (for example, the third batch of semiconductor dies 2000c). Then, as shown in FIG. 4P, subsequent processes such as the removal of the carrier board 30 (marked in FIG. 4O), the formation of grooves 64, and the placement of solder balls 66 are also performed, and the methods are disclosed in the first embodiment and are not repeated herein. Finally, die sawing is performed. As shown in 4Q, the semiconductor stack structure 3000B with ultra thin dies after die sawing is mainly different from the semiconductor stack structure 3000A with ultra thin dies shown in FIG. 1V of the first embodiment in that, in the semiconductor stack structure 3000B with ultra thin dies, the dielectric layer (for example, the first dielectric layer 70′, the second dielectric layer 74, the third dielectric layer 78′, or the fourth dielectric layer 82′) is formed between the conductive structures (for example, the wafer conductive structures 34, the first die conductive structures 44a, the second die conductive structures 44b, or the third die conductive structures 44c), and the bonding dielectric layer (for example, the first bonding dielectric layer 36A, the second bonding dielectric layer 46A, the third bonding dielectric layer 48A, or the fourth bonding dielectric layer 50A) is further formed on the above conductive structures and the dielectric layer. Conductive blocks (for example, the first conductive blocks 72, the second conductive blocks 76, the third conductive blocks 80, or the fourth conductive blocks 84) are formed in the bonding dielectric layer. This allows the first bonding layer 22b of each batch of semiconductor dies to be hybrid bonded with the bonding dielectric layer having the conductive blocks, where the conductive pillars 40 of the first bonding layer 22b are electrically connected to the conductive blocks, respectively.

In contrast, in the semiconductor stack structure 3000A with ultra thin dies shown in FIG. 1V, the first bonding layer 22b of each batch of semiconductor dies is directly hybrid bonded with the bonding dielectric layer (for example, the first bonding dielectric layer 36, the second bonding dielectric layer 46, or the third bonding dielectric layer 48) formed between the conductive structures (for example, the wafer conductive structures 34, the first die conductive structures 44a, or the second die conductive structures 44b), and the conductive pillars 40 of the first bonding layer 22b are electrically connected to the conductive structures respectively.

According to the above description, the semiconductor stack structure with ultra thin dies in the embodiments of the present invention can be applied to logic/memory or passive chip stacking. A multi-layer 3D die structure can be formed through continuous face-to-face stacking of semiconductor dies. The stop layer structure in each batch of semiconductor dies can create a robust etching stop mechanism, thereby preventing wafer warpage and total thickness variation (TTV). Because the second substrate part, the deep dielectric stop layer, and the dielectric stop layer have different etching selectivity ratios, the process window (process window) can be increased during the thinning process of each batch of semiconductor dies through continuous wet etching, dry etching, and chemical mechanical polishing processes, thereby improving the stability of the semiconductor stack structure with ultra thin dies. Because the overall thickness of each semiconductor chip layer is not greater than 12 micrometers, under the total chip thickness limit of 700 micrometers, the semiconductor stack structure with ultra thin dies in the embodiments of the present invention can be stacked up to more than 60 thinned semiconductor chip layers, meeting the requirements for high integration and speed, and providing good electrical characteristics and efficiency.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A method for manufacturing a semiconductor stack structure with ultra thin dies, comprising:
manufacturing a plurality of semiconductor wafers, wherein manufacturing steps for each of the semiconductor wafers comprise:
providing a semiconductor substrate having an active surface and a back surface opposite each other;
forming a stop layer structure in the semiconductor substrate to divide the semiconductor substrate into a first substrate part and a second substrate part, wherein the first substrate part is located between the stop layer structure and the active surface, the second substrate part is located between the stop layer structure and the back surface, the stop layer structure at least comprises a dielectric stop layer, and the dielectric stop layer is manufactured by performing an ion implantation process at a depth of the semiconductor substrate and performing a high-temperature treatment process, such that the dielectric stop layer is formed in a region for the ion implantation process;
sequentially forming an epitaxial layer, an active layer, a redistribution layer, and a first bonding layer on the active surface;
providing a carrier board and forming a second bonding layer on the carrier board;
selecting one of the semiconductor wafers as a first semiconductor wafer, and inverting the first semiconductor wafer to bond the first bonding layer of the first semiconductor wafer with the second bonding layer;
removing the second substrate part of the first semiconductor wafer and the stop layer structure to expose the first substrate part of the first semiconductor wafer;
forming a plurality of wafer conductive structures that penetrate the first substrate part, the epitaxial layer, and the active layer of the first semiconductor wafer to be connected to the redistribution layer, and thinning the first substrate part, such that the wafer conductive structures protrude out of the first substrate part;
forming a first bonding dielectric layer on the first substrate part of the first semiconductor wafer to cover the wafer conductive structures, and thinning the first bonding dielectric layer to expose the wafer conductive structures;
selecting another one of the semiconductor wafers as a second semiconductor wafer, disposing a plurality of conductive pillars on the first bonding layer of the second semiconductor wafer to be electrically connected to the redistribution layer, and performing die sawing on the second semiconductor wafer to form a first batch of semiconductor dies and a second batch of semiconductor dies that are to be stacked;
inverting the first batch of semiconductor dies, such that the first bonding layer of the first batch of semiconductor dies and the first bonding dielectric layer are opposite each other and bonded together through a hybrid bonding technology, wherein the conductive pillars of the first batch of semiconductor dies are electrically connected to the wafer conductive structures, respectively;
performing a back surface grinding process on the second substrate part of the first batch of semiconductor dies to thin the second substrate part;
forming on the first bonding dielectric layer a first packaging colloid that covers the first batch of semiconductor dies and fills up gaps between the first batch of semiconductor dies;
removing part of the first packaging colloid and removing the second substrate part and the stop layer structure of the first batch of semiconductor dies to expose the first substrate part of the first batch of semiconductor dies;
forming a plurality of first die conductive structures that penetrate the first substrate part, the epitaxial layer, and the active layer of the first batch of semiconductor dies to be connected to the redistribution layer, and thinning the first substrate part and the first packaging colloid, such that the first die conductive structures protrude out of the first substrate part of the first batch of semiconductor dies; and
forming a second bonding dielectric layer on the first substrate part and the first packaging colloid of the first batch of semiconductor dies to cover the first die conductive structures, and thinning the second bonding dielectric layer to expose the first die conductive structures.

2. The method for manufacturing a semiconductor stack structure with ultra thin dies according to claim 1, after the first die conductive structures are exposed, further comprising:
inverting the second batch of semiconductor dies, such that the first bonding layer of the second batch of semiconductor dies and the second bonding dielectric layer are opposite each other and bonded together through the hybrid bonding technology, wherein the conductive pillars of the second batch of semiconductor dies respectively correspond to and are electrically connected to the first die conductive structures;
forming on the second bonding dielectric layer a second packaging colloid that covers the second batch of semiconductor dies and fills up gaps between the second batch of semiconductor dies;
removing part of the second packaging colloid and removing the second substrate part and the stop layer structure of the second batch of semiconductor dies to expose the first substrate part of the second batch of semiconductor dies;
forming a plurality of second die conductive structures that penetrate the first substrate part, the epitaxial layer, and the active layer of the second batch of semiconductor dies to be connected to the redistribution layer, and thinning the first substrate part and the second packaging colloid, such that the second die conductive structures protrude out of the first substrate part of the second batch of semiconductor dies; and
forming a third bonding dielectric layer on the first substrate part and the second packaging colloid of the second batch of semiconductor dies to cover the second die conductive structures, and thinning the third bonding dielectric layer to expose the second die conductive structures.

3. The method for manufacturing a semiconductor stack structure with ultra thin dies according to claim 2, further comprising:
providing a dummy carrier board, forming a third bonding layer on the dummy carrier board, and bonding the third bonding layer with the third bonding dielectric layer;
removing the carrier board to expose the second bonding layer;
forming a plurality of grooves in the second bonding layer and the first bonding layer of the first semiconductor wafer to expose the redistribution layer of the first semiconductor wafer;
respectively disposing a plurality of solder balls in the grooves, and electrically connecting the solder balls to the redistribution layer; and
performing die sawing at a position of the second batch of semiconductor dies.

4. The method for manufacturing a semiconductor stack structure with ultra thin dies according to claim 1, wherein a method for forming the stop layer structure comprises:
performing a first ion implantation process at a first depth of the semiconductor substrate;
performing a second ion implantation process at a second depth of the semiconductor substrate, wherein the second depth is different from the first depth, and an element used for the first ion implantation process is different from an element used for the second ion implantation process; and
performing a high-temperature treatment process, such that a deep dielectric stop layer is formed in a region for the first ion implantation process, and the dielectric stop layer is formed in a region for the second ion implantation process, the dielectric stop layer being located between the deep dielectric stop layer and the active surface.

5. The method for manufacturing a semiconductor stack structure with ultra thin dies according to claim 4, wherein the element used for the first ion implantation process and the element used for the second ion implantation process are selected from boron, carbon, nitrogen, fluorine, phosphorus, argon, and arsenic.

6. The method for manufacturing a semiconductor stack structure with ultra thin dies according to claim 4, wherein the step of removing the second substrate part of the first semiconductor wafer and the stop layer structure comprises:
performing a back surface grinding process to remove part of the second substrate part from a side of the second substrate part away from the stop layer structure;
performing a wet etching process to remove the other part of the second substrate part, so as to expose the deep dielectric stop layer, wherein an etching selectivity ratio of the deep dielectric stop layer to the second substrate part is between 1/10 and 1/300;
performing a dry etching process to remove the deep dielectric stop layer, so as to expose the dielectric stop layer, wherein an etching selectivity ratio of the dielectric stop layer to the deep dielectric stop layer is between ⅕ and 1/100; and
performing a dry etching process to remove the dielectric stop layer, so as to expose the first substrate part, wherein an etching selectivity ratio of the first substrate part to the dielectric stop layer is between ⅕ and 1/100.

7. The method for manufacturing a semiconductor stack structure with ultra thin dies according to claim 4, wherein after the first packaging colloid is formed to cover the first batch of semiconductor dies, the step of removing part of the first packaging colloid and removing the second substrate part and the stop layer structure of the first batch of semiconductor dies comprises:
performing a chemical mechanical polishing process to polish part of the first packaging colloid on the second substrate part of the first batch of semiconductor dies;
performing a wet etching process to remove the thinned second substrate part of the first batch of semiconductor dies and part of the first packaging colloid, so as to expose the deep dielectric stop layer of the first batch of semiconductor dies, wherein an etching selectivity ratio of the deep dielectric stop layer to the second substrate part is between 1/10 and 1/300;
performing a dry etching process to remove the deep dielectric stop layer of the first batch of semiconductor dies and part of the first packaging colloid, so as to expose the dielectric stop layer of the first batch of semiconductor dies, wherein an etching selectivity ratio of the dielectric stop layer to the deep dielectric stop layer is between ⅕ and 1/100; and
performing a dry etching process to remove the dielectric stop layer of the first batch of semiconductor dies, so as to expose the first substrate part of the first batch of semiconductor dies, wherein an etching selectivity ratio of the first substrate part to the dielectric stop layer is between ⅕ and 1/100.

8. The method for manufacturing a semiconductor stack structure with ultra thin dies according to claim 1, wherein the epitaxial layer is deposited on the active surface through a metal-organic chemical vapor deposition process, and at least one active element is further formed on the epitaxial layer.

9. The method for manufacturing a semiconductor stack structure with ultra thin dies according to claim 1, wherein the step of forming a plurality of wafer conductive structures comprises:
forming a plurality of through holes penetrating the first substrate part, the epitaxial layer, and the active layer of the first semiconductor wafer;
sequentially conformally forming an insulating layer and a barrier layer on side walls and bottom walls of the through holes; and
disposing a conductive material in the through holes.

10. The method for manufacturing a semiconductor stack structure with ultra thin dies according to claim 1, wherein the step of forming a plurality of first die conductive structures comprises:
forming a plurality of through holes penetrating the first substrate part and the epitaxial layer of the first batch of semiconductor dies;
sequentially conformally forming an insulating layer and a barrier layer on side walls and bottom walls of the through holes; and
disposing a conductive material in the through holes.

11. The method for manufacturing a semiconductor stack structure with ultra thin dies according to claim 1, wherein the first bonding layer and the second bonding layer are bonded together through a melting bonding process.

12. A method for manufacturing a semiconductor stack structure with ultra thin dies, comprising:
manufacturing a plurality of semiconductor wafers, wherein manufacturing steps for each of the semiconductor wafers comprise:
providing a semiconductor substrate having an active surface and a back surface opposite each other;
forming a stop layer structure in the semiconductor substrate to divide the semiconductor substrate into a first substrate part and a second substrate part, wherein the first substrate part is located between the stop layer structure and the active surface, the second substrate part is located between the stop layer structure and the back surface, the stop layer structure at least comprises a dielectric stop layer, and the dielectric stop layer is manufactured by performing an ion implantation process at a depth of the semiconductor substrate and performing a high-temperature treatment process, such that the dielectric stop layer is formed in a region for the ion implantation process; and
sequentially forming an epitaxial layer, an active layer, a redistribution layer, and a first bonding layer on the active surface;
providing a carrier board and forming a second bonding layer on the carrier board;
selecting one of the semiconductor wafers as a first semiconductor wafer, and inverting the first semiconductor wafer to bond the first bonding layer of the first semiconductor wafer with the second bonding layer;
removing the second substrate part of the first semiconductor wafer and the stop layer structure to expose the first substrate part of the first semiconductor wafer;
forming a plurality of wafer conductive structures that penetrate the first substrate part, the epitaxial layer, and the active layer of the first semiconductor wafer to be connected to the redistribution layer, and thinning the first substrate part, such that the wafer conductive structures protrude out of the first substrate part;
forming a first dielectric layer on the first substrate part of the first semiconductor wafer to cover the wafer conductive structures, and thinning the first dielectric layer to expose the wafer conductive structures;
forming a first bonding dielectric layer on the first dielectric layer and the wafer conductive structures, wherein a plurality of first conductive blocks penetrate the first bonding dielectric layer, and the first conductive blocks are electrically connected to the wafer conductive structures, respectively;
selecting another one of the semiconductor wafers as a second semiconductor wafer, disposing a plurality of conductive pillars on the first bonding layer of the second semiconductor wafer to be electrically connected to the redistribution layer, and performing die sawing on the second semiconductor wafer to form a first batch of semiconductor dies and a second batch of semiconductor dies that are to be stacked;
inverting the first batch of semiconductor dies, such that the first bonding layer of the first batch of semiconductor dies and the first bonding dielectric layer are opposite each other and bonded together through a hybrid bonding technology, wherein the conductive pillars of the first batch of semiconductor dies respectively correspond to and are electrically connected to the first conductive blocks;
performing a back surface grinding process on the second substrate part of the first batch of semiconductor dies to thin the second substrate part;
forming on the first bonding dielectric layer a first packaging colloid that covers the first batch of semiconductor dies and fills up gaps between the first batch of semiconductor dies;
removing part of the first packaging colloid and removing the second substrate part and the stop layer structure of the first batch of semiconductor dies to expose the first substrate part of the first batch of semiconductor dies;
forming a plurality of first die conductive structures that penetrate the first substrate part, the epitaxial layer, and the active layer of the first batch of semiconductor dies to be connected to the redistribution layer, and thinning the first substrate part of the first batch of semiconductor dies, such that the first die conductive structures protrude out of the first substrate part;
forming a second dielectric layer on the first packaging colloid and the first substrate part of the first batch of semiconductor dies, and thinning the second dielectric layer to expose the first die conductive structure; and
forming a second bonding dielectric layer on the second dielectric layer and the first die conductive structures, wherein a plurality of second conductive blocks penetrate the second bonding dielectric layer, and the second conductive blocks are electrically connected to the first die conductive structures, respectively.

13. The method for manufacturing a semiconductor stack structure with ultra thin dies according to claim 12, after the second bonding dielectric layer penetrated by the second conductive blocks is formed, further comprising:
inverting the second batch of semiconductor dies, such that the first bonding layer of the second batch of semiconductor dies and the second bonding dielectric layer are opposite each other and bonded together through the hybrid bonding technology, wherein the conductive pillars of the second batch of semiconductor dies respectively correspond to and are electrically connected to the second conductive blocks;
performing a back surface grinding process on the second substrate part of the second batch of semiconductor dies to thin the second substrate part;
forming on the second bonding dielectric layer a second packaging colloid that covers the second batch of semiconductor dies and fills up gaps between the second batch of semiconductor dies;
removing part of the second packaging colloid and removing the second substrate part and the stop layer structure of the second batch of semiconductor dies to expose the first substrate part of the second batch of semiconductor dies;
forming a plurality of second die conductive structures that penetrate the first substrate part, the epitaxial layer, and the active layer of the second batch of semiconductor dies to be connected to the redistribution layer, and thinning the first substrate part of the second batch of semiconductor dies, such that the second die conductive structures protrude out of the first substrate part;
forming a third dielectric layer on the second packaging colloid and the first substrate part of the second batch of semiconductor dies, and thinning the third dielectric layer to expose the second die conductive structure; and
forming a third bonding dielectric layer on the third dielectric layer and the second die conductive structures, wherein a plurality of third conductive blocks penetrate the third bonding dielectric layer, and the third conductive blocks are electrically connected to the second die conductive structures, respectively.

14. The method for manufacturing a semiconductor stack structure with ultra thin dies according to claim 13, further comprising:
providing a dummy carrier board, forming a third bonding layer on the dummy carrier board, and bonding the third bonding layer with the third bonding dielectric layer;
removing the carrier board to expose the second bonding layer;
forming a plurality of grooves in the second bonding layer and the first bonding layer of the first semiconductor wafer to expose the redistribution layer of the first semiconductor wafer;
respectively disposing a plurality of solder balls in the grooves, and electrically connecting the solder balls to the redistribution layer; and
performing die sawing at a position of the second batch of semiconductor dies.
